(19) United States
(12) Patent Application Publication
(10) Pub. No.: US 2026/0186186 A1
(43) Pub. Date: Jul. 2, 2026

(54) MANUFACTURING METHOD OF OPTICAL LAMINATE, MANUFACTURING METHOD OF POLARIZING PLATE, OPTICAL LAMINATE, POLARIZING PLATE, AND ORGANIC ELECTROLUMINESCENT DISPLAY DEVICE

(71) Applicant: FUJIFILM Corporation, Tokyo (JP)

(72) Inventors: Yoshiaki HISAKADO, Minamiashigara-shi, Kanagawa (JP); Jun ISHIYAMA, Minamiashigara-shi, Kanagawa (JP)

(73) Assignee: FUJIFILM Corporation, Tokyo (JP)

(21) Appl. No.: 19/543,885

(22) Filed: Feb. 19, 2026

Related U.S. Application Data
(63) Continuation of application No. PCT/JP2024/030487, filed on Aug. 27, 2024.

(30) Foreign Application Priority Data
Sep. 22, 2023 (JP) 2023-159068
Jan. 23, 2024 (JP) 2024-008138

(51) Int. Cl. G02B 5/30; H10K 59/50; H10K 59/80

(52) U.S. Cl. CPC G02B 5/3016; H10K 59/50; H10K 59/8791

(57) ABSTRACT

A manufacturing method of an optical laminate is provided that suppresses unevenness in interference color when used in an organic EL display device. The method includes directly applying a liquid crystal composition for forming an optically anisotropic layer (B) having a phase difference that does not provide a λ/4 function onto an optically anisotropic layer (A) formed by immobilizing an aligned liquid crystal compound. The optically anisotropic layer (A) satisfies at least one of a requirement that the layer is subjected to a surface treatment or a requirement that the layer is formed from a liquid crystal composition containing a photoalignment polymer, and has a phase difference that does not provide a λ/4 function. The laminate formed thereby provides a λ/4 function. An optical laminate, polarizing plate, and organic EL display device are also provided.

### CROSS-REFERENCE TO RELATED APPLICATIONS

This application is a Continuation of PCT International Application No. PCT/JP2024/030487 filed on Aug. 27, 2024, which claims priority under 35 U.S.C. § 119 (a) to Japanese Patent Application No. 2023-159068 filed on Sep. 22, 2023, and Japanese Patent Application No. 2024-008138 filed on Jan. 23, 2024. The above applications are hereby expressly incorporated by reference, in their entirety, into the present application.

### BACKGROUND OF THE INVENTION

### 1. Field of the Invention

The present invention relates to a manufacturing method of an optical laminate, a manufacturing method of a polarizing plate, an optical laminate, a polarizing plate, and an organic electroluminescent display device.

### 2. Description of the Related Art

In the related art, in order to suppress adverse effects due to external light reflection, a circular polarization plate has been used in an organic electroluminescent display device (hereinafter, also referred to as an “organic EL display device”). In order to meet the demand for thinning of the organic EL display device to which the circular polarization plate is applied, thinning of a retardation layer included in the circular polarization plate is also required. As the retardation layer which achieves thinning, for example, WO2022/045187A discloses an optical laminate including an optically anisotropic layer obtained by polymerizing a polymerizable liquid crystal composition.

### SUMMARY OF THE INVENTION

As a result of studying a polarizing plate including the optical laminate disclosed in WO2022/045187A, the present inventors have found that, in a case where the organic EL display device to which the polarizing plate is applied is observed from an oblique direction, unevenness in thickness of an adhesion layer between the optically anisotropic layers causes unevenness in interference color to be visually recognized under a certain specific light source. In particular, the problem is particularly noticeable in a case where a thin adhesion layer having a thickness of about several μm is applied. The above-described unevenness in interference color is visually recognized as unevenness in tint in a form of interference fringes having different tints (tint difference) in a plane.

An object of the present invention is to provide a manufacturing method of an optical laminate, which can manufacture an optical laminate in which the unevenness in interference color in an oblique direction is suppressed in a case where the optical laminate is applied to an organic EL display device.

Another object of the present invention is to provide a manufacturing method of a polarizing plate, an optical laminate, a polarizing plate, and an organic electroluminescent display device.

The present inventors have found that the above-described objects can be achieved by the following configurations.
[1] A manufacturing method of an optical laminate, comprising:
a step of directly applying a liquid crystal composition for forming an optically anisotropic layer (B) having a phase difference not providing a λ/4 function onto an optically anisotropic layer (A) formed by immobilizing an aligned liquid crystal compound, the optically anisotropic layer (A) satisfying the following requirement 1 or 2 and having a phase difference not providing a λ/4 function, to form a laminate having a λ/4 function,
the requirement 1: the optically anisotropic layer (A) is subjected to a surface treatment,
the requirement 2: the optically anisotropic layer (A) is formed of a liquid crystal composition containing a photo alignment polymer.
[2] The manufacturing method of an optical laminate according to [1],
in which the optically anisotropic layer (A) is a negative uniaxial optically anisotropic layer.
[3] The manufacturing method of an optical laminate according to [1] or [2],
in which the optically anisotropic layer (B) is an optically anisotropic layer formed by immobilizing a twisted-aligned rod-like liquid crystal compound having a helical axis along a thickness direction.
[4] The manufacturing method of an optical laminate according to any one of [1] to [3], further comprising:
a step of directly applying a liquid crystal composition for forming a C-plate onto the laminate to form a C-plate, or a step of bonding a C-plate to the laminate through an adhesion layer.
[5] A manufacturing method of a polarizing plate, comprising:
laminating the optical laminate obtained by the manufacturing method of an optical laminate according to any one of [1] to [4] and a polarizer to obtain a polarizing plate.
[6] An optical laminate having a λ/4 function, comprising:
an optically anisotropic layer (A) which is formed by immobilizing an aligned liquid crystal compound, satisfies the following requirement 1 or 2, and has a phase difference not providing a λ/4 function;
an optically anisotropic layer (B) having a phase difference not providing a λ/4 function;
an adhesion layer 2; and
a C-plate,
in which the optically anisotropic layer (A), the optically anisotropic layer (B), the adhesion layer 2, and the C-plate are arranged adjacent to one another in this order,
the requirement 1: the optically anisotropic layer (A) is subjected to a surface treatment,
the requirement 2: the optically anisotropic layer (A) is formed of a liquid crystal composition containing a photo alignment polymer.
[7] The optical laminate according to [6],
in which the adhesion layer 2 has a refractive index of 1.53 to 1.64.
[8] The optical laminate according to [6] or [7],
in which silicon is present at an interface between the optically anisotropic layer (A) and the optically anisotropic layer (B).
[9] A polarizing plate comprising:
a polarizer;
an adhesion layer 1;
an optically anisotropic layer (A) which is formed by immobilizing an aligned liquid crystal compound, satisfies the following requirement 1 or 2, and has a phase difference not providing a λ/4 function;
an optically anisotropic layer (B) having a phase difference not providing a λ/4 function;
an adhesion layer 2; and
a C-plate,
in which the polarizer, the adhesion layer 1, the optically anisotropic layer (A), the optically anisotropic layer (B), the adhesion layer 2, and the C-plate are arranged adjacent to one another in this order, and
a laminate of the optically anisotropic layer (A) and the optically anisotropic layer (B) has a λ/4 function,
the requirement 1: the optically anisotropic layer (A) is subjected to a surface treatment,
the requirement 2: the optically anisotropic layer (A) is formed of a liquid crystal composition containing a photo alignment polymer.
[10] An organic electroluminescent display device comprising:
the optical laminate according to any one of [6] to [8].
[11] An organic electroluminescent display device comprising:
the polarizing plate according to [9].

According to the present invention, it is possible to provide a manufacturing method of an optical laminate, which can manufacture an optical laminate in which the unevenness in interference color in an oblique direction is suppressed in a case where the optical laminate is applied to an organic EL display device.

In addition, according to the present invention, it is possible to provide a manufacturing method of a polarizing plate, an optical laminate, a polarizing plate, and an organic electroluminescent display device.

### BRIEF DESCRIPTION OF THE DRAWINGS

FIG. 1 is an example of a schematic cross-sectional view of an embodiment of the polarizing plate of the present invention.

FIG. 2 is a diagram showing a relationship between an absorption axis of a polarizer and in-plane slow axes of an optically anisotropic layer (A) and an optically anisotropic layer (B) in the embodiment of the polarizing plate according to the present invention.

FIG. 3 is a schematic diagram showing an angle relationship between the absorption axis of the polarizer and the in-plane slow axes of the optically anisotropic layer (A) and the optically anisotropic layer (B) in a case of being observed in a direction of a white arrow in FIG. 1.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Any numerical range expressed using “to” in the present specification refers to a range including the numerical values before and after the “to” as a lower limit value and an upper limit value, respectively.

In addition, in the present specification, substances corresponding to respective components may be used alone or in combination of two or more kinds thereof. Here, in a case where two or more kinds of substances are used in combination for each component, the content of the component indicates the total content of the substances used in combination, unless otherwise specified.

In addition, in the present specification, “(meth)acryl” denotes “acryl” or “methacryl”, and “(meth)acryloyl” denotes “acryloyl” or “methacryloyl”.

Next, terms used in the present specification will be described.

In the present specification, a slow axis is defined at 550 nm unless otherwise specified.

In the present specification, Re (λ) and Rth (λ) represent an in-plane retardation and a thickness-direction retardation at a wavelength λ, respectively. Unless otherwise specified, the wavelength λ is 550 nm.

In the present invention, Re(λ) and Rth(λ) are values measured at the wavelength of λ in AxoScan (manufactured by Axometrics, Inc.). By inputting an average refractive index ((nx+ny+nz)/3) and a film thickness (d (μm)) in AxoScan,
a slow axis direction) (°),

$$Re ( λ ) = R 0 ( λ ) ; and$$

$$Rth ( λ ) = ( ( nx + ny ) / 2 - nz ) \times d$$

are calculated.

Although R0 (λ) is displayed as a numerical value calculated by AxoScan, it means Re (λ).

In the present specification, the refractive indices nx, ny, and nz are measured using an Abbe refractometer (NAR-4T, manufactured by Atago Co., Ltd.) and using a sodium lamp (λ=589 nm) as a light source. In addition, in a case of measuring the wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethylmethacrylate (1.49), and polystyrene (1.59).

“Light” in the present specification means actinic rays or radiation, and for example, means a bright line spectrum of a mercury lamp, far ultraviolet rays typified by an excimer laser, extreme ultraviolet rays (EUV light), X-rays, ultraviolet rays, electron beams (EB), or the like. Among these, ultraviolet rays are preferable.

In the present specification, “visible light” means light having a wavelength of 380 to 780 nm. In addition, in the present specification, a measurement wavelength is 550 nm unless otherwise specified.

In addition, in the present specification, a relationship between angles (for example, “orthogonal”, “parallel”, and the like) is intended to include a range of errors acceptable in the art to which the present invention belongs. Specifically, it means that an angle is within an error range of less than ±10° with respect to the exact angle, and the error with respect to the exact angle is preferably within a range of ±5° or less and more preferably within a range of ±3° or less.

In the present specification, a horizontal alignment of a rod-like liquid crystal compound refers to a state in which a major axis of a liquid crystal compound is arranged horizontally and in the same orientation with respect to the surface of the layer.

Here, the “horizontal” does not require to be strictly horizontal, but is intended to mean an alignment in which a tilt angle formed by an average molecular axis of the liquid crystal compound in the layer and the surface of the layer is less than 20°.

In addition, the “same orientation” does not require that the major axis of the liquid crystal compound is arranged strictly in the same orientation with respect to the surface of the layer, but is intended to mean that, in a case where the orientation of the slow axis is measured at any 20 positions in the plane, the maximum difference between slow axis orientations among the slow axis orientations at 20 positions (difference between two slow axis orientations having the maximum difference among the 20 slow axis orientations) is less than 10°.

A vertical alignment of a disk-like liquid crystal compound refers to a state in which a disc axis of the liquid crystal compound is arranged vertically and in the same orientation with respect to the surface of the layer.

Here, the “vertical” does not require to be strictly perpendicular, but is intended to mean an alignment in which a tilt angle formed by the disc plane of the liquid crystal compound in the layer and the surface of the layer is 70° to 110°.

In addition, the “same orientation” does not require that the major axis of the liquid crystal compound is arranged strictly in the same orientation with respect to the surface of the layer, but is intended to mean that, in a case where the orientation of the slow axis is measured at any 20 positions in the plane, the maximum difference between slow axis orientations among the slow axis orientations at 20 positions (difference between two slow axis orientations having the maximum difference among the 20 slow axis orientations) is less than 10°.

In the present specification, an optically anisotropic layer refers to a layer formed by immobilizing an aligned liquid crystal compound.

The “immobilized” state is a state in which the alignment of a liquid crystal compound is maintained. Specifically, the “immobilized” state is more preferably a state in which, in a temperature range of usually 0° C. to 50° C. or in a temperature range of −30° C. to 70° C. under more severe conditions, the layer has no fluidity and a fixed alignment morphology can be stably maintained without causing a change in the alignment morphology due to an external field or an external force.

The unevenness in interference color, which is the object of the present invention, refers to a phenomenon in which, in a case where a polarizer, an optically anisotropic layer (A) having a phase difference not providing a λ/4 function, and an optically anisotropic layer (B) having a phase difference not providing a λ/4 function are arranged in this order, light incident from the polarizer side which is reflected at an interface between an adhesion layer and the optically anisotropic layer in a case where the adhesion layer is present between the optically anisotropic layer (A) and the optically anisotropic layer (B) and the light passes through the polarizer again to be visually recognized as unevenness in interference color. In a case where the unevenness in interference color occurs, even in a case where the λ/4 function is exhibited by two or more optically anisotropic layers and a circular polarization plate is disposed on an organic EL display device, a change in tint occurs in a case of black display under a certain specific light source.

In the present invention, a manufacturing method of directly applying a liquid crystal composition for forming the optically anisotropic layer (B) onto the optically anisotropic layer (A) to form the optically anisotropic layer (B) is used, and the interface reflection occurring at the interface present between the optically anisotropic layer (A) and the optically anisotropic layer (B) is suppressed to reduce the unevenness in interference color.

### [Optical Laminate]

Hereinafter, the optical laminate according to the embodiment of the present invention will be described in detail.

The optical laminate according to the embodiment of the present invention is an optical laminate manufactured by a manufacturing method of an optical laminate, including a step of directly applying a liquid crystal composition for forming an optically anisotropic layer (B) having a phase difference not providing a λ/4 function onto an optically anisotropic layer (A) formed by immobilizing an aligned liquid crystal compound, the optically anisotropic layer (A) satisfying the following requirement 1 or 2 and having a phase difference not providing a λ/4 function, to form a laminate having a λ/4 function. That is, the optical laminate according to the embodiment of the present invention is a laminate including an optically anisotropic layer (A) which is formed by immobilizing an aligned liquid crystal compound, satisfies the following requirement 1 or the requirement 2, and has a phase difference not providing a λ/4 function, and an optically anisotropic layer (B) having a phase difference not providing a λ/4 function, in which the optically anisotropic layer (A) and the optically anisotropic layer (B) are arranged adjacent to each other.

Requirement 1: the optically anisotropic layer (A) is subjected to a surface treatment.

Requirement 2: the optically anisotropic layer (A) is formed of a liquid crystal composition containing a photo alignment polymer.

Hereinafter, the optically anisotropic layer (A) in the present invention may be referred to as a specific optically anisotropic layer (A); and the optically anisotropic layer (B) in the present invention may be referred to as a specific optically anisotropic layer (B).

Specifically, the λ/4 function is a function of converting linearly polarized light having a specific wavelength into circularly polarized light (or circularly polarized light into linearly polarized light).

### [Optically Anisotropic Layer (A)]

The optically anisotropic layer (A) in the present invention is an optically anisotropic layer which is formed by immobilizing an aligned liquid crystal compound, satisfies the following requirement 1 or 2, and has a phase difference not providing a λ/4 function.

Requirement 1: the optically anisotropic layer (A) is subjected to a surface treatment.

Requirement 2: the optically anisotropic layer (A) is formed of a liquid crystal composition containing a photo alignment polymer.

Here, the liquid crystal compound can be classified into a rod-like type and a disk-like type according to the shape thereof. Furthermore, each type includes a low-molecular-type and a high-molecular-type. The “high-molecular-weight” generally refers to a compound having a degree of polymerization of 100 or more (Polymer Physics-Phase Transition Dynamics, written by Masao Doi, p. 2, published by Iwanami Shoten, 1992). In the present invention, any liquid crystal compound can be used, and a rod-like liquid crystal compound or a discotic liquid crystal compound (disk-like liquid crystal compound) is preferable. In addition, a liquid crystal compound which is a monomer or has a relatively low molecular weight with a degree of polymerization of less than 100 is preferable.

In addition, from the viewpoint of fixing alignment, the liquid crystal compound preferably has a polymerizable group. Examples of such a polymerizable group include an acryloyl group, a methacryloyl group, an epoxy group, and a vinyl group. In the following, the liquid crystal compound having a polymerizable group is abbreviated as “polymerizable liquid crystal compound”.

By polymerizing such a polymerizable liquid crystal compound, the alignment of the liquid crystal compound can be fixed. After immobilizing the liquid crystal compound by polymerization, it is no longer necessary to exhibit liquid crystallinity.

As the rod-like liquid crystal compound, azomethines, azoxys, cyano biphenyls, cyanophenyl esters, benzoic acid esters, cyclohexane carboxylic acid phenyl esters, cyanophenyl cyclohexanes, cyano-substituted phenyl pyrimidines, alkoxy-substituted phenyl pyrimidines, phenyl dioxanes, tolanes, and alkenylcyclohexylbenzonitriles are preferably used. The immobilization of the rod-like liquid crystal compound can be performed by introducing a polymerizable group into a terminal structure of the rod-like liquid crystal compound (same as the disk-like liquid crystal described later), and using polymerization and curing reaction. A specific example thereof is described in JP2006-209073A, in which a polymerizable nematic rod-like liquid crystal compound is cured with ultraviolet rays.

In addition, as well as the above-described low-molecular-weight liquid crystal compound, a high-molecular-weight liquid crystal compound can also be used. The high-molecular-weight liquid crystal compound is a polymer having a side chain corresponding to the above-described low-molecular-weight liquid crystal compound. JP1993-53016A (JP-H5-53016A) and the like describes an optical compensation sheet formed of the high-molecular-weight liquid crystal compound.

As the disk-like liquid crystal compound, benzene derivatives described in C. Destrade et al.'s report, “Mol. Cryst.”, vol. 71, page 111 (1981); truxene derivatives described in C. Destrade et al.'s report, “Mol. Cryst.”, vol. 122, page 141 (1985) and “Physics lett, A”, vol. 78, page 82 (1990); cyclohexane derivatives describes in B. Kohne et al.'s report, “Agnew. Chem.”, vol. 96, page 70 (1984); and azacrown-based or phenyl acetylene-based macrocycles described in J. M. Lehn et al.'s report, “J. Chem. Commun.”, page 1794 (1985) and J. Zhang et al.'s report, “J. Am. Chem. Soc.”, vol. 116, page 2655 (1994) are included.

The molecule of the disk-like liquid crystal compound also includes a compound exhibiting liquid crystallinity, in which a linear alkyl group, an alkoxy group, or a substituted benzoyloxy group is radially substituted as a side chain of a mother nucleus with respect to a molecular center. A compound in which molecules or molecular aggregates have rotation symmetry and to which certain alignment can be imparted is preferable. In an optically anisotropic layer formed of a composition containing the disk-like liquid crystal compound, the disk-like liquid crystal compound does not need to exhibit liquid crystallinity in a final state in which the disk-like liquid crystal compound is contained in the optically anisotropic layer. For example, in a case where a low-molecular-weight disk-like liquid crystal molecule having a group which reacts by heat or light is polymerized by heating or light irradiation to be high-molecular-weight, the liquid crystallinity is lost, but an optically anisotropic layer containing such a high-molecular-weight compound can also be used in the present invention. Preferable examples of the disk-like liquid crystal compound include compounds described in JP1996-050206A (JP-H8-050206A). In addition, the polymerization of the disk-like liquid crystal molecules is described in JP1996-027284A (JP-H8-027284A).

As a method of immobilizing the disk-like liquid crystal molecules by polymerization, there is a method of bonding a polymerizable group as a substituent to a disk-like core of the disk-like liquid crystal molecule and polymerizing the disk-like liquid crystal molecules. A compound in which the disk-like core and the polymerizable group are bonded through a linking group is preferable, whereby the compound can maintain the alignment state even under the polymerization reaction. Examples of the disk-like liquid crystal molecule having a polymerizable group include compounds described in paragraphs to of JP2000-155216A.

In the present invention, from the viewpoint of improving the tint in the oblique direction, the optically anisotropic layer (A) is preferably a negative uniaxial optically anisotropic layer, and more preferably an optically anisotropic layer formed by immobilizing a vertically aligned disk-like liquid crystal compound.

In addition, an in-plane retardation of the optically anisotropic layer (A) at a wavelength of 550 nm is preferably 140 to 220 nm, and more preferably 150 to 200 nm from the viewpoint of further suppressing the tinting of black in a case of being visually recognized from a front direction or an oblique direction of the organic EL display device to which the optical laminate according to the embodiment of the present invention is applied (hereinafter, also simply referred to as “viewpoint of further suppressing the tinting of black”).

In addition, from the viewpoint of increasing refractive index anisotropy and thinning, a refractive index of the optically anisotropic layer (A) is preferably 1.50 or more and 1.70 or less, and more preferably 1.55 or more and 1.65 or less. The above-described refractive index is a refractive index at a wavelength of 550 nm.

In the present invention, an angle between an in-plane slow axis of the optically anisotropic layer (A) and an absorption axis of a polarizer is preferably 40° to 85°, more preferably 50° to 85°, and still more preferably 65° to 85°.

In a case where the optical laminate according to the embodiment of the present invention has an elongated shape, an angle between a longitudinal direction of the optical laminate and the in-plane slow axis of the optically anisotropic layer (A) is preferably 40° to 85°, more preferably 50° to 85°, and still more preferably 65° to 85°.

A thickness of the optically anisotropic layer (A) is preferably 0.5 μm or more, more preferably 0.8 μm or more, and still more preferably 1.0 μm or more. In addition, the thickness of the optically anisotropic layer (A) is preferably 5.0 μm or less, more preferably 4.0 μm or less, and still more preferably 3.0 μm or less.

The above-described thickness is obtained by measuring thicknesses of any five or more points of the optically anisotropic layer (A) and arithmetically averaging the measured values.

### [Optically Anisotropic Layer (B)]

The optically anisotropic layer (B) included in the optical laminate according to the embodiment of the present invention is a layer formed of a liquid crystal composition described later, and includes an optically anisotropic layer formed by immobilizing an aligned liquid crystal compound.

Here, examples of the liquid crystal compound include the same compounds as those described in the optically anisotropic layer (A) described above.

In the present invention, from the viewpoint of improving the reflectivity and the tint in the oblique direction, it is more preferable that the optically anisotropic layer (B) is composed of an optically anisotropic layer formed by immobilizing a twisted-aligned rod-like liquid crystal compound having a helical axis along a thickness direction.

As described above, the optically anisotropic layer (B) is preferably an optically anisotropic layer in which a twist-aligned rod-like liquid crystal compound having a helical axis along a thickness direction is immobilized, that is, it is preferably a layer in which a chiral nematic phase having a so-called helical structure is fixed. In a case of forming the above-described layer, it is preferable to use a liquid crystal composition obtained by mixing a liquid crystal compound exhibiting a nematic liquid crystal phase and a chiral agent described later.

A value of a product And of a refractive index anisotropy Δn of the optically anisotropic layer (B) measured at a wavelength of 550 nm and a thickness d of the optically anisotropic layer (B) is preferably 140 to 220 nm, and from the viewpoint of further suppressing the tinting of black, it is more preferably 150 to 210 nm and still more preferably 160 to 200 nm.

The refractive index anisotropy Δn means refractive index anisotropy of an optically anisotropic layer.

The Δnd is measured using an AxoScan (polarimeter) device manufactured by Axometrics, Inc. and using device analysis software of Axometrics, Inc.

A twisted angle of the liquid crystal compound (twisted angle of the liquid crystal compound in an alignment direction) is preferably 90°±30° (within a range of 60° to 120°), and from the viewpoint of further suppressing the tinting of black, it is more preferably 90°±20° (within a range of 70° to 110°) and still more preferably 90°±10° (within a range of 80° to 100°).

The twisted angle is measured using an AxoScan (polarimeter) device manufactured by Axometrics, Inc. and using device analysis software of Axometrics, Inc.

In addition, the “twist-aligned liquid crystal compound” is intended to that the liquid crystal compound from one main surface to the other main surface of the optically anisotropic layer (B) is twisted around the thickness direction of the optically anisotropic layer (B) as an axis. Along with this, the alignment direction (in-plane slow axis direction) of the liquid crystal compound varies depending on the position of the optically anisotropic layer (B) in the thickness direction.

An angle between the in-plane slow axis of the optically anisotropic layer (A) and an in-plane slow axis of the optically anisotropic layer (B) at the surface on the optically anisotropic layer (A) side is preferably 0° to 20° and more preferably 0° to 15°.

A thickness of the optically anisotropic layer (B) is not particularly limited, but is preferably 0.5 μm or more, more preferably 0.8 μm or more, and still more preferably 1.0 μm or more. In addition, the thickness of the optically anisotropic layer (B) is preferably 5.0 μm or less, more preferably 3.0 μm or less, and still more preferably 2.5 μm or less.

The above-described thickness is obtained by measuring thicknesses of any five or more points of the optically anisotropic layer (B) and arithmetically averaging the measured values.

### (Chiral Agent)

Various known chiral agents can be used as the chiral agent used for forming the twisted alignment of the liquid crystal compound. The chiral agent has a function of inducing a helical structure of a liquid crystal compound. Since the sense or helical pitch of the helix induced by the chiral agent is different depending on a compound, the chiral compound may be selected according to the purpose.

As the chiral agent, a known compound can be used, but it is preferable to have a cinnamoyl group. Examples of the chiral agent include compounds described in Liquid Crystal Device Handbook, Chapter 3 articles 4-3, TN, chiral agent for STN, page 199, Japan Society for the Promotion of Science No. 142 committee version, 1989, and JP2003-287623A, JP2002-302487A, JP2002-080478A, JP2002-080851A, JP2010-181852A, and JP2014-034581A.

The chiral agent generally includes an asymmetric carbon atom, but an axially asymmetric compound or a surface asymmetric compound, which does not have the asymmetric carbon atom, can also be used as the chiral agent. Examples of the axially chiral compound or the planar chiral compound include binaphthyl, helicene, paracyclophane, and derivatives thereof. The chiral agent may have a polymerizable group.

In a case where both the chiral agent and the liquid crystal compound have a polymerizable group, a polymer having a repeating unit induced from the polymerizable liquid crystal compound and a repeating unit induced from the chiral agent can be formed by a polymerization reaction between the polymerizable chiral agent and the polymerizable liquid crystal compound.

In this aspect, the polymerizable group of the polymerizable chiral agent is preferably the same polymerizable group as the polymerizable group of the polymerizable liquid crystal compound. Accordingly, the polymerizable group of the chiral agent is preferably an unsaturated polymerizable group, an epoxy group, or an aziridinyl group, more preferably an unsaturated polymerizable group, and still more preferably an ethylenically unsaturated polymerizable group.

In addition, the chiral agent may be a liquid crystal compound.

As the chiral agent, an isosorbide derivative, an isomannide derivative, a binaphthyl derivative, or the like can be preferably used. As the isosorbide derivative, a commercially available product such as LC-756 manufactured by BASF may be used.

A content of the chiral agent in the liquid crystal composition is preferably 0.01 to 200 mol % and more preferably 1 to 30 mol % with respect to the amount of the liquid crystal compound.

### [Optically Anisotropic Layer (C)]

It is preferable that the optical laminate according to the embodiment of the present invention further includes an optically anisotropic layer (C).

The optically anisotropic layer (C) is preferably a C-plate. Among these, the optically anisotropic layer (C) is more preferably a layer formed by immobilizing a vertically aligned rod-like liquid crystal compound, that is, a positive C-plate.

The C-plate is a plate that satisfies any of Expression (C1) or Expression (C2) in a case where a refractive index in an in-plane slow axis direction is defined as nx, a refractive index in a direction orthogonal to the in-plane slow axis in the plane is defined as ny, and a refractive index in a thickness direction is defined as nz. In a case where Expression (C1) is satisfied, the C-plate is a so-called positive C-plate; and in a case where Expression (C2) is satisfied, the C-plate is a so-called negative C-plate. The positive C-plate has an Rth showing a negative value and the negative C-plate has an Rth showing a positive value.

$$Expression ( C 1 ) nz > nx \approx ny$$

$$Expression ( C 2 ) nz < nx \approx ny$$

The symbol “≈” encompasses not only a case where both sides are completely the same as each other but also a case where the both sides are substantially the same as each other. The expression “substantially the same” means that, for example, a case where (nx−ny)×d (in which d is a thickness of a film) is 0 to 10 nm and preferably 0 to 5 nm is also included in “nx≈ny”.

An in-plane retardation of the optically anisotropic layer (C) at a wavelength of 550 nm is preferably 0 to 10 nm.

The above-described in-plane retardation is more preferably 0 to 5 nm from the viewpoint of further suppressing the tinting of black.

In addition, a thickness direction retardation of the optically anisotropic layer (C) at a wavelength of 550 nm is preferably −120 to −20 nm.

The above-described thickness direction retardation is more preferably −110 to −30 nm and still more preferably −100 to −40 nm from the viewpoint of further suppressing the tinting of black.

A thickness of the optically anisotropic layer (C) is not particularly limited, but is preferably 0.2 μm or more, more preferably 0.3 μm or more, and still more preferably 0.5 μm or more. In addition, the thickness of the optically anisotropic layer (C) is preferably 4.0 μm or less, more preferably 3.0 μm or less, and still more preferably 2.0 μm or less.

The above-described thickness is obtained by measuring thicknesses of any five or more points of the optically anisotropic layer (C) and arithmetically averaging the measured values.

In a case where the optical laminate according to the embodiment of the present invention includes the optically anisotropic layer (C), a lamination order of each layer is not particularly limited; but it is preferable that the optically anisotropic layer (A), the optically anisotropic layer (B), and the optically anisotropic layer (C) are laminated in this order.

An aspect of the optical laminate according to the embodiment of the present invention (hereinafter, abbreviated as “specific aspect”) is that the optical laminate includes the optically anisotropic layer (A) formed by immobilizing a vertically aligned disk-like liquid crystal compound, includes the optically anisotropic layer (B) formed by immobilizing a twisted-aligned rod-like liquid crystal compound having a helical axis along a thickness direction, and includes the optically anisotropic layer (C) formed by immobilizing a vertically aligned rod-like liquid crystal compound.

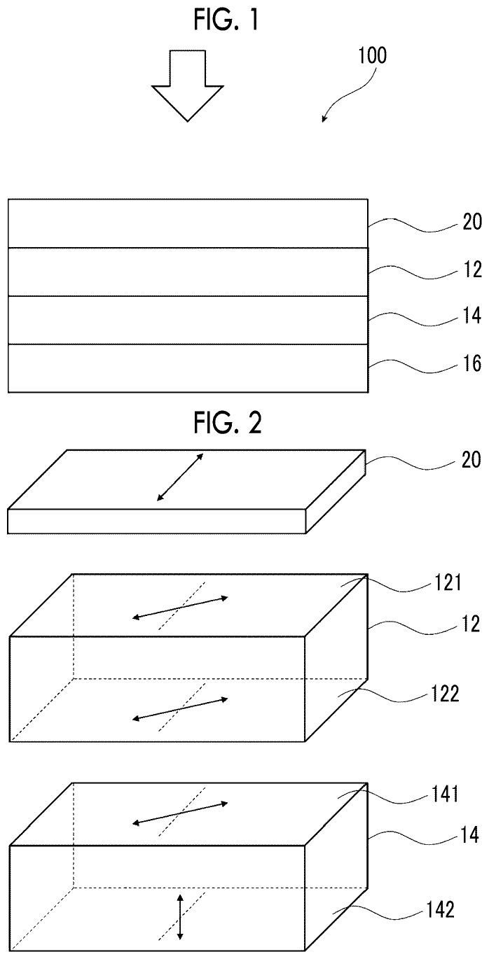

An example of a polarizing plate including the optical laminate according to the above-described specific aspect will be described with reference to FIGS. 1 to 3.

FIG. 1 is a schematic cross-sectional view of an embodiment of a polarizing plate 100.

In addition, FIG. 2 is a diagram showing a relationship between an absorption axis of a polarizer 20 and in-plane slow axes of an optically anisotropic layer (A) 12 and an optically anisotropic layer (B) 14 in the polarizing plate 100 shown in FIG. 1. An arrow in the polarizer 20 in FIG. 2 represents the absorption axis, and arrows in the optically anisotropic layer (A) 12 and the optically anisotropic layer (B) 14 represent the in-plane slow axes in the layers, respectively.

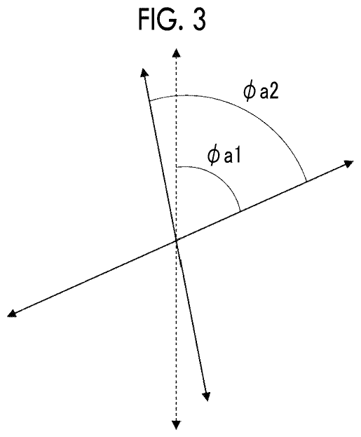

In addition, FIG. 3 is a diagram showing a relationship of an angle between the absorption axis (broken line) of the polarizer 20 and the in-plane slow axes (solid lines) of each of the optically anisotropic layer (A) 12 and the optically anisotropic layer (B) 14, upon observation from the white arrow in FIG. 1.

A rotation angle of the in-plane slow axes is represented by a positive angle value in a counterclockwise direction and a negative angle value in a clockwise direction, with respect to the absorption axis of the polarizer 20 (0°), upon observation from the white arrow in FIG. 1.

In addition, whether the twisted direction of the liquid crystal compound is a right-handed twist (clockwise) or a left-handed twist (counterclockwise) is determined with reference to the in-plane slow axis on the surface of the front side (the polarizer 20 side) in the optically anisotropic layer (B) 14, upon observation from the white arrow in FIG. 1.

As shown in FIG. 1, the polarizing plate 100 includes the polarizer 20, the optically anisotropic layer (A) 12, the optically anisotropic layer (B) 14, and the optically anisotropic layer (C) 16 in this order. In the optical laminate according to the embodiment of the present invention, the optically anisotropic layer (A) 12 and the optically anisotropic layer (B) 14 are directly laminated. A layer (for example, an adhesion layer; not shown) may be provided between the optically anisotropic layer (B) 14 and the optically anisotropic layer (C) 16 and between the polarizer 20 and the optically anisotropic layer (A).

As shown in FIG. 2 and FIG. 3, an angle φa1 formed by the absorption axis of the polarizer 20 and the in-plane slow axis of the optically anisotropic layer (A) 12 is 76°. More specifically, the in-plane slow axis of the optically anisotropic layer (A) 12 is rotated by −76° (76° clockwise) with respect to the absorption axis of the polarizer 20. FIG. 2 and FIG. 3 show an aspect in which the in-plane slow axis of the optically anisotropic layer (A) 12 is at a position of −76°, but the present invention is not limited to this aspect. The in-plane slow axis of the optically anisotropic layer (A) 12 is preferably within a range of −40° to −85°, more preferably within a range of −50° to −85°, and still more preferably within a range of −65° to −85°. That is, the angle formed by the absorption axis of the polarizer 20 and the in-plane slow axis of the optically anisotropic layer (A) 12 is preferably within a range of 40° to 85°, more preferably within a range of 50° to 85°, and still more preferably within a range of 65° to 85°.

In the optically anisotropic layer (A) 12 shown in FIG. 2, the in-plane slow axis of the optically anisotropic layer (A) 12 at a surface 121 on the polarizer 20 side and the in-plane slow axis of the optically anisotropic layer (A) 12 at a surface 122 on the optically anisotropic layer (B) 14 side are parallel to each other.

As shown in FIG. 2 and FIG. 3, the in-plane slow axis of the optically anisotropic layer (A) 12 and the in-plane slow axis of the optically anisotropic layer (B) 14 at a surface 141 on the optically anisotropic layer (A) 12 side are parallel to each other.

The present invention is not limited to the aspect, and the angle formed by the in-plane slow axis of the optically anisotropic layer (A) 12 and the in-plane slow axis of the optically anisotropic layer (B) 14 at the surface 141 on the first optically anisotropic layer 12 side is preferably within a range of 0° to 20°.

As described above, the optically anisotropic layer (B) 14 is an optically anisotropic layer formed by immobilizing a twisted-aligned rod-like liquid crystal compound having a helical axis along a thickness direction. Therefore, as shown in FIG. 2 and FIG. 3, the in-plane slow axis of the optically anisotropic layer (B) 14 at the surface 141 on the optically anisotropic layer (A) 12 side and the in-plane slow axis of the optically anisotropic layer (B) 14 at a surface 142 on the side opposite to the optically anisotropic layer (A) 12 side form the above-described twisted angle (in FIG. 2, 81°). That is, an angle φ2 formed by the in-plane slow axis of the optically anisotropic layer (B) 14 at the surface 141 on the optically anisotropic layer (A) 12 side and the in-plane slow axis of the optically anisotropic layer (B) 14 at the surface 142 on the side opposite to the optically anisotropic layer (A) 12 side is 81°. More specifically, a twisted direction of the rod-like liquid crystal compound in the optically anisotropic layer (B) 14 is a left-handed twist (counterclockwise), and a twisted angle thereof is 81°.

Although FIG. 2 and FIG. 3 show an aspect in which the twisted angle of the rod-like liquid crystal compound in the optically anisotropic layer (B) 14 is 81°, the present invention is not limited to this aspect. As described above, the twisted angle of the rod-like liquid crystal compound is preferably within a range of 80°±30°. That is, the angle formed by the in-plane slow axis of the optically anisotropic layer (B) 14 at the surface 141 on the optically anisotropic layer (A) 12 side and the in-plane slow axis of the optically anisotropic layer (B) 14 at the surface 142 on the side opposite to the optically anisotropic layer (A) 12 side is preferably within a range of 80±30°.

As described above, in the aspect of FIG. 2 and FIG. 3, the in-plane slow axis of the optically anisotropic layer (A) 12 is rotated clockwise by 81°, and the twisted direction of the rod-like liquid crystal compound in the optically anisotropic layer (B) 14 is counterclockwise (left-handed twist) with reference to the absorption axis of the polarizer 20, upon observation of the polarizing plate 100 from the polarizer 20 side.

In FIG. 2 and FIG. 3, the aspect in which the twisted direction of the rod-like liquid crystal compound is counterclockwise has been described in detail, but an aspect in which the twisted direction of the rod-like liquid crystal compound is clockwise may be configured as long as the relationship of the predetermined angle is satisfied. More specifically, an aspect in which the in-plane slow axis of the optically anisotropic layer (A) 12 is rotated counterclockwise by 81°, and the twisted direction of the rod-like liquid crystal compound in the optically anisotropic layer (B) 14 is clockwise (right-handed twist) with reference to the absorption axis of the polarizer 20, upon observation of the polarizing plate 100 from the polarizer 20 side, may be used.

That is, in the polarizing plate 100 shown in FIG. 1, in a case where the in-plane slow axis of the optically anisotropic layer (A) is rotated clockwise within a range of 40° to 85° (preferably 50° to 85° and more preferably 65° to 85°) with reference to the absorption axis of the polarizer 20, upon observation of the polarizing plate 100 from the polarizer 20 side, it is preferable that the twisted direction of the rod-like liquid crystal compound in the optically anisotropic layer (B) is counterclockwise with reference to the in-plane slow axis of the optically anisotropic layer (B) at the surface on the optically anisotropic layer (A) side.

In addition, in the polarizing plate 100 shown in FIG. 1, in a case where the in-plane slow axis of the optically anisotropic layer (A) is rotated counterclockwise within a range of 40° to 85° (preferably 50° to 85° and more preferably 65° to 85°) with reference to the absorption axis of the polarizer 20, upon observation of the polarizing plate 100 from the polarizer 20 side, it is preferable that the twisted direction of the rod-like liquid crystal compound in the optically anisotropic layer (B) is clockwise with reference to the in-plane slow axis of the optically anisotropic layer (B) at the surface on the optically anisotropic layer (A) side. Even in a case where the twisted direction of the rod-like liquid crystal compound in the optically anisotropic layer (B) is clockwise, it is preferable that the angle formed by the in-plane slow axis of the optically anisotropic layer (A) and the in-plane slow axis of the optically anisotropic layer (B) at the surface on the optically anisotropic layer (A) side is within a range of 0° to 20°.

### [Adhesion Layer]

The optical laminate according to the embodiment of the present invention may include an adhesion layer such as a pressure sensitive adhesive layer and an adhesive layer, between the polarizer and the optically anisotropic layer (A), between the optically anisotropic layer (B) and the optically anisotropic layer (C), or the like. Examples of the adhesion layer include known pressure sensitive adhesive layers and known adhesive layers.

As described in JP1999-149015A (JP-H11-149015A), in general, it is preferable to adjust the refractive index of an adhesive or a pressure sensitive adhesive for each of layers forming a laminated wavelength plate or a circular polarization plate, from the viewpoint of suppressing reflection by adjusting the refractive index between the layers. A difference in refractive index with an object to be bonded is preferably 0.1 or less, more preferably 0.08 or less, still more preferably 0.06 or less, and most preferably 0.03 or less. From the viewpoint of suppressing the unevenness in interference color in the oblique direction in a case of being applied to the organic EL display device, a refractive index of the adhesion layer is preferably 1.50 to 1.70 and more preferably 1.53 to 1.64. The above-described refractive index is a refractive index at a wavelength of 550 nm.

A high-refractive-index adhesive or a high-refractive-index pressure sensitive adhesive may be used in a case of disposing the adhesion layer between optically anisotropic layers formed of liquid crystal compounds.

In order to increase the refractive index, it is also preferable to use a high-refractive-index monomer or high-refractive-index metal fine particles.

The high-refractive-index monomer preferably has a benzene ring skeleton in the molecule. Examples of a monofunctional monomer having a benzene ring skeleton in the molecule include ethoxylated o-phenylphenol (meth)acrylate, o-phenylphenol glycidyl ether (meth)acrylate, para-cumylphenoxyethylene glycol (meth)acrylate, 2-methacryloyloxyethyl phthalate, 2-acryloyloxyethyl phthalate, 2-acryloyloxyethyl-2-hydroxyethyl phthalate, 2-acryloyloxypropyl phthalate, phenoxyethyl (meth)acrylate, EO-modified phenol (meth)acrylate, phenoxydiethylene glycol (meth)acrylate, EO-modified nonylphenol (meth)acrylate, PO-modified nonylphenol (meth)acrylate, phenyl glycidyl ether (meth)acrylate, neopentyl glycol benzoate (meth)acrylate, nonylphenoxypolyethylene glycol (meth)acrylate, ECH-modified phenoxy (meth)acrylate, benzyl (meth)acrylate, and vinyl carbazole.

Examples of a component constituting the inorganic particles include a metal oxide, a metal nitride, a metal oxynitride, and a metal simple substance. Examples of a metal atom contained in the above-described metal oxide, metal nitride, metal oxynitride, and metal simple substance include a titanium atom, a silicon atom, an aluminum atom, a cobalt atom, and a zirconium atom. Specific examples of the inorganic particles include inorganic oxide particles such as alumina particles, alumina hydrate particles, silica particles, zirconia particles, and a clay mineral (for example, smectite). From the viewpoint of refractive index, fine particles of zirconium oxide are preferable. The refractive index can be adjusted to a predetermined value by changing the amount of the inorganic fine particles. An average particle diameter of the inorganic fine particles in the layer is preferably 1 to 120 nm, more preferably 1 to 60 nm, and still more preferably 2 to 40 nm in a case where zirconium oxide is used as a main component.

A thickness of the adhesion layer is not particularly limited, but is preferably 0.5 μm or more, and more preferably 0.8 μm or more. In addition, the thickness of the adhesion layer is usually 50 μm or less, preferably 20 μm or less, and more preferably 5 μm or less.

The above-described thickness is obtained by observing a cross section of the adhesion layer with a scanning electron microscope (SEM).

Among these, in the optical laminate according to the embodiment of the present invention, it is preferable that the optically anisotropic layer (A), the optically anisotropic layer (B), an adhesion layer 2, and the C-plate are arranged adjacent to one another in this order or that the optically anisotropic layer (A), the optically anisotropic layer (B), and the C-plate are arranged adjacent to one another in this order; and it is more preferable that the optically anisotropic layer (A), the optically anisotropic layer (B), an adhesion layer 2, and the C-plate are arranged adjacent to one another in this order.

The adhesion layer 2 is a layer which adheres the optically anisotropic layer (B) and the C-plate, and specific examples and suitable aspects thereof are the same as those of the adhesion layer described above.

In the optical laminate according to the embodiment of the present invention, it is also preferable that silicon is present at an interface between the optically anisotropic layer (A) and the optically anisotropic layer (B). Specifically, the presence of silicon at the above-described interface is a state in which silicon is present on at least one of the surface of the optically anisotropic layer (A) on the optically anisotropic layer (B) side or the surface of the optically anisotropic layer (B) on the optically anisotropic layer (A) side; and it is preferable that silicon is present on the surface of the optically anisotropic layer (A) on the optically anisotropic layer (B) side.

An aspect of the silicon is not particularly limited, and examples thereof include a part of components (for example, a surfactant described later) in each optically anisotropic layer and decomposition products or reaction products thereof.

The presence of silicon at the interface can be confirmed, for example, by a method of measuring the exposed interface by X-ray photoelectron spectroscopy.

Examples of a method of causing silicon to be present at the above-described interface include a method of forming the optically anisotropic layer (A) using a liquid crystal composition containing a component including a silicon atom.

A thickness of the optical laminate according to the embodiment of the present invention is not particularly limited, but is preferably 2.0 μm or more, more preferably 3.0 μm or more, and still more preferably 3.5 μm or more. In addition, the thickness of the optical laminate is usually 15.0 μm or less, preferably 10.0 μm or less, and more preferably 5.0 μm or less.

The above-described thickness is obtained by observing a cross section of the laminate with SEM.

### [Manufacturing Method of Optical Laminate]

Hereinafter, the manufacturing method of the optical laminate according to the embodiment of the present invention will be described in detail.

The manufacturing method of the optical laminate according to the embodiment of the present invention includes a step of directly applying a liquid crystal composition for forming an optically anisotropic layer (B) having a phase difference not providing a λ/4 function onto an optically anisotropic layer (A) formed by immobilizing an aligned liquid crystal compound, the optically anisotropic layer (A) satisfying the following requirement 1 or 2 and having a phase difference not providing a λ/4 function, to form a laminate having a λ/4 function.

Requirement 1: the optically anisotropic layer (A) is subjected to a surface treatment.

Requirement 2: the optically anisotropic layer (A) is formed of a liquid crystal composition containing a photo alignment polymer.

Hereinafter, a specific procedure thereof will be described.

First, the liquid crystal composition is applied onto a support (preferably an elongated support) to form the optically anisotropic layer (A). Here, it is necessary for the optically anisotropic layer (A) to impart a function of aligning the optically anisotropic layer (B) to be formed on the optically anisotropic layer (A). Examples of a method of imparting the alignment function to the optically anisotropic layer (A) include a method of performing a surface treatment after forming the optically anisotropic layer (A) (the requirement 1: the optically anisotropic layer (A) is subjected to a surface treatment), and a method of containing a photo alignment polymer in the liquid crystal composition for forming the optically anisotropic layer (A) and then curing the liquid crystal composition to obtain the optically anisotropic layer (A) to impart the alignment function to the optically anisotropic layer (A) (the requirement 2: the optically anisotropic layer (A) is formed of a liquid crystal composition containing a photo alignment polymer).

Next, the liquid crystal composition for forming the optically anisotropic layer (B) is directly applied onto the obtained optically anisotropic layer (A) to form the optically anisotropic layer (B), thereby obtaining the laminate.

In a case where the optical laminate according to the embodiment of the present invention satisfies the requirement 1, it is preferable that the liquid crystal composition for forming the optically anisotropic layer (B) is applied onto a surface of the optically anisotropic layer (A), on which the surface treatment is performed; and in a case where the optical laminate according to the embodiment of the present invention satisfies the requirement 2, it is preferable that the liquid crystal composition for forming the optically anisotropic layer (B) is applied onto a surface of the optically anisotropic layer (A), on which the photo alignment polymer is present (preferably, a surface on a side where the photo alignment polymer is unevenly distributed).

Optical performance of the optically anisotropic layer (A) and the optically anisotropic layer (B) may be appropriately adjusted such that the optical laminate including the optically anisotropic layer (A) and the optically anisotropic layer (B) has the λ/4 function.

The manufacturing method of the optical laminate according to the embodiment of the present invention may further include a step of bonding an optically anisotropic layer (C) (preferably, a C-plate) formed by separately applying a liquid crystal composition (preferably, a liquid crystal composition for forming a C-plate) onto a substrate to the laminate through an adhesion layer, or may include a method of directly applying a liquid crystal composition (preferably, a liquid crystal composition for forming a C-plate) onto the optically anisotropic layer (B) to form an optically anisotropic layer (C) (preferably, a C-plate) after imparting the alignment function to the optically anisotropic layer (B) by the same method as the above-described method.

It is preferable that the specific optically anisotropic layer (A) is a negative uniaxial optically anisotropic layer, and the specific optically anisotropic layer (B) is an optically anisotropic layer formed by immobilizing a twisted-aligned rod-like liquid crystal compound having a helical axis along a thickness direction.

The reverse configuration, that is, the specific optically anisotropic layer (A) is an optically anisotropic layer formed by immobilizing a twisted-aligned rod-like liquid crystal compound having a helical axis along a thickness direction and the specific optically anisotropic layer (B) is a negative uniaxial optically anisotropic layer is also possible. In a case of such an optical laminate, it is preferable to manufacture a polarizing plate described later by disposing the optically anisotropic layer (C) (preferably, the C-plate) on the optically anisotropic layer (A) side and disposing the polarizer on the optically anisotropic layer (B) side.

Hereinafter, the substrate, the liquid crystal composition, a method of forming the optically anisotropic layer formed of the liquid crystal composition, and the like will be described in detail.

### <Substrate>

The substrate is preferably a transparent substrate. The transparent substrate is intended to be a substrate in which the transmittance of visible light is 60% or more, and the transmittance is preferably 80% or more and more preferably 90% or more.

A thickness direction retardation value (Rth(550)) of the substrate at a wavelength of 550 nm is not particularly limited, and is preferably −110 to 110 nm and more preferably −80 to 80 nm.

An in-plane retardation value (Re(550)) of the substrate at a wavelength of 550 nm is not particularly limited, and is preferably 0 to 50 nm, more preferably 0 to 30 nm, and still more preferably 0 to 10 nm.

A polymer having excellent optical performance transparency, mechanical strength, heat stability, moisture shielding property, isotropy, and the like is preferable as a material for forming the substrate.

Examples of a polymer film which can be used as the substrate include a cellulose acylate film (for example, a cellulose triacetate film (refractive index: 1.48), a cellulose diacetate film, a cellulose acetate butyrate film, or a cellulose acetate propionate film), a polyolefin film such as polyethylene or polypropylene, a polyester film such as polyethylene terephthalate or polyethylene naphthalate, a polyether sulfone film, a polyacrylic film such as polymethyl methacrylate, a polyurethane film, a polycarbonate film, a polysulfone film, a polyether film, a polymethylpentene film, a polyether ketone film, a (meth)acrylonitrile film, and a film of a polymer having an alicyclic structure (a norbornene-based resin (ARTON: trade name, manufactured by JSR Corporation) or an amorphous polyolefin (ZEONEX: trade name, manufactured by Zeon Corporation)).

Among these, a material for the polymer film is preferably triacetyl cellulose, polyethylene terephthalate, or a polymer having an alicyclic structure, and more preferably triacetyl cellulose.

The substrate may contain various additives (for example, an optical anisotropy adjuster, a wavelength dispersion adjuster, a fine particle, a plasticizer, an ultraviolet inhibitor, a deterioration inhibitor, a release agent, and the like).

A thickness of the substrate is not particularly limited, but is preferably 10 to 200 μm, more preferably 10 to 100 μm, and still more preferably 20 to 90 μm. In addition, the substrate may consist of a plurality of layers laminated. The substrate may be subjected to a surface treatment (for example, a glow discharge treatment, a corona discharge treatment, an ultraviolet (UV) treatment, or a flame treatment) on the surface of the substrate in order to improve adhesion with a layer provided thereon.

In addition, an adhesion layer (undercoat layer) may be provided on the substrate.

In addition, in order to impart slipperiness in a transport step and prevent a back surface and a front surface from sticking to each other after winding, a polymer layer in which inorganic particles having an average particle diameter of approximately 10 to 100 nm are mixed in a solid content mass ratio of 5% to 40% by mass may be disposed on one side of the substrate.

The substrate may be a so-called temporary support. That is, after manufacturing the optical laminate according to the embodiment of the present invention, the substrate may be peeled off from the optically anisotropic layer.

In addition, the surface of the substrate may be directly subjected to a rubbing treatment. That is, a substrate which has been subjected to the rubbing treatment may be used. A direction of the rubbing treatment is not particularly limited, and an optimum direction is appropriately selected according to the direction in which the liquid crystal compound is desired to be aligned.

As the rubbing treatment, a treatment method widely adopted as an alignment treatment step of an alignment film of a liquid crystal display (LCD) can be applied. That is, a method of obtaining alignment by rubbing the surface of the substrate in a certain direction with paper, gauze, felt, rubber, nylon fiber, polyester fiber, or the like can be used.

An alignment film may be disposed on the substrate.

The alignment film can be formed by methods such as rubbing treatment of an organic compound (preferably a polymer), oblique vapor deposition of an inorganic compound, formation of a layer having microgrooves, or accumulation of an organic compound (for example, ω-tricosanoic acid, dioctadecylmethylammonium chloride, or methyl stearate) by the Langmuir-Blodgett method (LB film).

Furthermore, there is also known an alignment film capable of expressing an alignment function by application of an electric field, application of a magnetic field, or light (preferably polarized light) irradiation.

Examples of the alignment film also include a photo-alignment film.

A thickness of the alignment film is not particularly limited as long as it can exhibit an alignment function, but is preferably 0.01 to 5.0 μm, more preferably 0.05 to 3.0 μm, and still more preferably 0.5 to 1.0 μm.

The alignment film may be peelable from the optically anisotropic layer together with the substrate.

### <Liquid Crystal Composition>

The liquid crystal compound contained in the liquid crystal composition for forming the optically anisotropic layer is as described above. As described above, a rod-like liquid crystal compound and a disk-like liquid crystal compound are appropriately selected according to the characteristics of an optically anisotropic layer to be formed.

A content of the liquid crystal compound in the liquid crystal composition is preferably 60% to 99% by mass and more preferably 70% to 98% by mass with respect to the total solid content of the liquid crystal composition.

The solid content means a component capable of forming the optically anisotropic layer, excluding a solvent, and even in a case where a component itself is in a liquid state, such a component is regarded as the solid content.

The liquid crystal composition may contain a compound other than the liquid crystal compound.

For example, the liquid crystal composition for forming the optically anisotropic layer (A) described above may contain a photo alignment polymer. The liquid crystal composition for forming an optically anisotropic layer other than the optically anisotropic layer (A) (for example, the optically anisotropic layer (B)) may contain a photo alignment polymer.

As the photo alignment polymer, a polymer having a photo-aligned group and a surface-segregating group is preferable.

A main chain of the polymer is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable.

Among these, a skeleton selected from the group consisting of a (meth)acrylic skeleton, a siloxane-based skeleton, and a cycloolefin-based skeleton is more preferable, and a (meth)acrylic skeleton is still more preferable.

The term “(meth)acrylic” is a general term for acrylic and methacrylic.

Suitable examples of the photo-aligned group include a group having a skeleton of at least one derivative selected from the group consisting of a cinnamic acid derivative, a coumarin derivative, a chalcone derivative, a maleimide derivative, and a benzophenone derivative, and a group having a skeleton of at least one compound selected from the group consisting of an azobenzene compound, a stilbene compound, a spiropyran compound, a cinnamic acid compound, and a hydrazono-β-ketoester compound. Among these photo-aligned groups, from the reason that liquid crystal alignment properties of the optically anisotropic layer formed in the upper layer are more favorable even with a small exposure amount, a group selected from the group consisting of a cinnamoyl group, an azobenzene group, a chalconyl group, and a coumarin group is preferable, and a cinnamoyl group is more preferable.

As the surface-segregating group, it is preferable to have a substituent including a fluorine atom or a silicon atom. By using such a photo alignment polymer, the photo alignment polymer is likely to be unevenly distributed on the surface of the optically anisotropic layer (A), and the optically anisotropic layer (B) formed on the optically anisotropic layer (A) can be directly aligned more efficiently.

As such a photo alignment polymer, a copolymer having a repeating unit including a photo-aligned group as in WO2018/216812A, and a repeating unit having a surface-segregating group at a terminal and including, as a linking group, a group which is cleaved by at least one action selected from the group consisting of light, heat, acid, and base; and a photo alignment polymer having a photo-aligned group and a surface-segregating group as described in WO2022/071410A (particularly, a copolymer including a repeating unit having a photo-aligned group and a repeating unit having a surface-segregating group) are known.

The liquid crystal composition for forming an optically anisotropic layer which is formed by immobilizing a twisted-aligned rod-like liquid crystal compound having a helical axis along a thickness direction preferably contains a chiral agent in order to twist-align the liquid crystal compound. Details of the chiral agent are as described above.

The liquid crystal composition may contain a polymerization initiator. The polymerization initiator used is selected according to the type of polymerization reaction, and examples thereof include a thermal polymerization initiator and a photopolymerization initiator.

A content of the polymerization initiator in the liquid crystal composition is preferably 0.01% to 20% by mass and more preferably 0.5% to 10% by mass with respect to the total solid content of the liquid crystal composition.

Examples of other components which may be contained in the liquid crystal composition include a polyfunctional monomer, an alignment control agent (a vertical alignment agent and a horizontal alignment agent), a surfactant, an adhesion improver, a plasticizer, a photoacid generator, and a solvent, in addition to the above-described components.

As the above-described surfactant, it is preferable to use a compound having a so-called leveling function of making a coated film flat. For example, a silicon atom-containing compound, a polyacrylate compound, or a fluorine atom-containing compound can be used.

Specifically, compounds, addition amounts, and the like described in paragraphs [0032] to [0036] of JP2020-098349A, paragraphs [0032] to [0039] of WO2020/149357A, and WO2023/054164A, and the like can be used as a reference.

In particular, from the viewpoint of reducing environmental pollution, the surfactant is preferably a silicon atom-containing compound or a polyacrylate compound, and more preferably a compound having a branched siloxane structure. Among these, a copolymer (surfactant) described in [Table 1] of WO2023/054164A is preferable.

A content of the surfactant is preferably 0.01% to 10%, more preferably 0.01% to 6.0%, and still more preferably 0.05% to 3.0% with respect to the total mass of the solid content of the liquid crystal composition.

From the same viewpoint of reducing environmental pollution, a content of fluorine atom in the surfactant is preferably low, and it is preferably 10% or less, more preferably 5% or less, and still more preferably 3% or less in terms of weight of the compound. The lower limit thereof is most preferably 0%, but a trace amount (for example, 0.01% to 1.0%) may be contained in a range in which the influence on environmental pollution is small.

In a case where the silicon atom-containing compound is used as the surfactant, silicon is present at the interface between the optically anisotropic layer (A) and the optically anisotropic layer (B).

### <Method of Forming Optically Anisotropic Layer>

A procedure of forming the optically anisotropic layer is not particularly limited, and examples thereof include a method of applying the above-described liquid crystal composition onto the substrate and performing a drying treatment as necessary (hereinafter, also simply referred to as “coating method”). In addition to the above-described substrate, the optically anisotropic layer may be formed by applying the liquid crystal composition onto another layer formed on the substrate. For example, the liquid crystal composition may be directly applied onto the optically anisotropic layer formed on the substrate to form the optically anisotropic layer.

The coating method is not particularly limited, and examples thereof include a wire bar coating method, an extrusion coating method, a direct gravure coating method, a reverse gravure coating method, and a die-coating method.

After the application of the composition, the coating film applied on the substrate may be subjected to a drying treatment as necessary. By performing the drying treatment, the solvent can be removed from the coating film.

A film thickness of the coating film is not particularly limited, but is preferably 0.1 to 20 μm, more preferably 0.2 to 15 μm, and still more preferably 0.5 to 10 μm.

Next, the formed coating film is subjected to an alignment treatment to align the liquid crystal compound in the coating film.

The alignment treatment can be performed by drying the coating film at room temperature or by heating the coating film. In a case of a thermotropic liquid crystal compound, a liquid crystal phase formed by the alignment treatment can generally be transferred by a change in temperature or pressure. In a case of a lyotropic liquid crystal compound, a liquid crystal phase formed by the alignment treatment can also be transferred by a compositional ratio such as an amount of solvent.

Conditions in a case of heating the coating film are not particularly limited, and the heating temperature is preferably 50° C. to 250° C. and more preferably 50° C. to 150° C., and the heating time is preferably 10 seconds to 10 minutes.

In addition, after the coating film is heated, the coating film may be cooled as necessary, before a curing treatment (light irradiation treatment) described later. The cooling temperature is preferably 20° C. to 200° C. and more preferably 30° C. to 150° C.

Next, it is preferable to perform a curing treatment on the coating film in which the liquid crystal compound is aligned.

A method of the curing treatment performed on the coating film in which the liquid crystal compound is aligned is not particularly limited, and examples thereof include a light irradiation treatment and a heat treatment. Among these, from the viewpoint of manufacturing suitability, a light irradiation treatment is preferable, and an ultraviolet irradiation treatment is more preferable.

Irradiation conditions of the light irradiation treatment are not particularly limited, and an irradiation amount of 50 to 1,000 mJ/cm² is preferable.

The atmosphere during the light irradiation treatment is not particularly limited, but is preferably a nitrogen atmosphere.

In addition, in a case where the liquid crystal composition contains the photo alignment polymer, from the viewpoint of imparting an alignment function, it is preferable to perform a photo-alignment treatment in a case of forming the optically anisotropic layer.

Examples of the photo-alignment treatment include a method of irradiating a coating film (including a cured film subjected to a curing treatment) of the liquid crystal composition with polarized light or irradiating the surface of the coating film with unpolarized light from an oblique direction. A timing of performing the photo-alignment treatment is not particularly limited, but it is more preferable to perform the photo-alignment treatment after the alignment treatment of the liquid crystal compound.

In the photo-alignment treatment, the polarized light to be irradiated is not particularly limited; and examples thereof include linearly polarized light, circularly polarized light, and elliptically polarized light, and linearly polarized light is preferable.

In addition, the “oblique direction” in which irradiation with unpolarized light is performed is not particularly limited as long as it is a direction inclined at a polar angle θ (0°<θ<90°) with respect to a normal direction of the surface of the coating film. θ can be appropriately selected according to the purpose, and is preferably 20° to 80°.

A wavelength of the polarized light or the unpolarized light is not particularly limited as long as the light is light to which the photo-aligned group is exposed. Examples thereof include ultraviolet rays, near-ultraviolet rays, and visible rays, and near-ultraviolet rays of 250 to 450 nm are preferable.

In addition, examples of a light source for the irradiation with polarized light or unpolarized light include a xenon lamp, a high-pressure mercury lamp, an ultra-high pressure mercury lamp, and a metal halide lamp. By using an interference filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

An integrated quantity of the polarized light or the unpolarized light is not particularly limited, and is preferably 1 to 300 mJ/cm² and more preferably 5 to 100 mJ/cm².

An illuminance of the polarized light or the unpolarized light is not particularly limited, and is preferably 0.1 to 300 mW/cm² and more preferably 1 to 100 mW/cm².

In addition, in a case where the optically anisotropic layer serving as the substrate (for example, the optically anisotropic layer (A)) is formed of a liquid crystal composition which does not contain the photo alignment polymer, it is preferable to perform a surface treatment on the optically anisotropic layer serving as the substrate and then apply a liquid crystal composition for forming the optically anisotropic layer to be laminated (for example, the optically anisotropic layer (B)). By performing the surface treatment, workability of the liquid crystal composition on the optically anisotropic layer serving as the substrate (coating cissing and the like) is improved, and the liquid crystal compound in the applied liquid crystal composition is likely to be aligned along the alignment state of the surface of the optically anisotropic layer serving as the substrate. Examples of the surface treatment include a glow discharge treatment, a corona discharge treatment, an ultraviolet (UV) treatment, and a flame treatment; and among these, a corona discharge treatment is preferable.

In a case where a corona treatment amount is small, aligning properties of the optically anisotropic layer to be laminated are insufficient; and in a case where the corona treatment amount is large, the manufacturing step may be contaminated. The corona treatment amount is preferably 10 to 200 W·min/m² and more preferably 20 to 100 W·min/m².

### [Polarizing Plate]

Hereinafter, the polarizing plate and the organic EL display device according to the embodiment of the present invention will be described in detail.

The polarizing plate according to the embodiment of the present invention includes a polarizer and the optical laminate according to the embodiment of the present invention. The polarizing plate can be used as a circular polarization plate. The circular polarization plate is an optical element which converts unpolarized light into circularly polarized light.

### [Polarizer]

The polarizer included in the polarizing plate according to the embodiment of the present invention may be a member having a function of converting natural light into specific linearly polarized light, and examples thereof include an absorption type polarizer.

The type of the polarizer is not particularly limited, and a commonly used polarizer can be used. Examples thereof include an iodine-based polarizer, a dye-based polarizer using a dichroic dye, and a polyene-based polarizer. The iodine-based polarizer and the dye-based polarizer are generally produced by adsorbing iodine or a dichroic dye on a polyvinyl alcohol, followed by stretching.

A protective film may be disposed on one side or both sides of the polarizer.

In addition, as described in WO2019/131943A and JP2017-083843A, a coating type polarizer produced by using and applying a liquid crystal compound and a dichroic organic coloring agent (for example, a dichroic azo coloring agent used for a light-absorbing anisotropic film described in WO2017/195833A), without using a polyvinyl alcohol as a binder, may be used as the polarizer. That is, the polarizer may be a polarizer formed of a composition containing a polymerizable liquid crystal compound.

The coating type polarizer is a technique which utilizes the alignment of the liquid crystal compound to align the dichroic organic coloring agent. As described in JP2012-083734A, in a case where the polymerizable liquid crystal compound exhibits smectic properties, it is preferable from the viewpoint of increasing the alignment degree. Alternatively, as described in WO2018/186503A, it is also preferable to crystallize a coloring agent from the viewpoint of increasing the alignment degree. WO2019/131943A describes a structure of a polymer liquid crystal which is preferred for increasing the alignment degree.

A polarizer in which a dichroic organic coloring agent is aligned using the aligning properties of the liquid crystal without carrying out stretching has the following characteristics. The above-described polarizer has many advantages, such as being able to be made very thin with a thickness of approximately 0.1 μm to 5 μm; as described in JP2019-194685A, being difficult for cracks to occur in a case of being bent, and being less likely to undergo thermal deformation; and as described in JP6483486B, exhibiting excellent durability even with a polarizing plate having a high transmittance of more than 50%.

By utilizing these advantages, the polarizer can be used in applications that require high brightness or small size and light weight, applications of a fine optical system, applications of forming into a portion having a curved surface, or applications of a flexible portion. Needless to say, it is also possible to peel off a support and transfer the polarizer for use.

From the viewpoint of power saving, a transmittance of the polarizer is preferably 40% or more, more preferably 44% or more, and still more preferably 50% or more in terms of luminosity corrected single transmittance. The upper limit thereof is not particularly limited, but is preferably 60% or less.

In the present invention, the luminosity corrected single transmittance of the polarizer is measured using an automatic polarizing film measuring device: VAP-7070 (manufactured by JASCO Corporation). The luminosity corrected single transmittance can be measured as follows. A sample (5 cm×5 cm) in which the polarizer is attached onto glass through a pressure sensitive adhesive is produced. In this case, a polarizing plate protective film is attached to the polarizer so as to be on the side opposite to the glass (air interface side). The luminosity corrected single transmittance is measured by setting the glass side of the sample toward a light source.

A configuration of the polarizer protective film is not particularly limited, and for example, may be a support or a coating layer, or may be a laminate of the support and the coating layer.

As the coating layer, a known layer can be used, and for example, a layer obtained by polymerizing and curing a polymer or a polyfunctional monomer may be used. Examples of the polymer include a (meth)acrylic polymer and a cycloolefin polymer. Examples of the polymerizable monomer include radically polymerizable or cationically polymerizable compounds.

A bonding surface between the polarizer and the protective film is not particularly limited, and for example, in order to suppress diffusion of potassium ions or iodide ions from the polarizer with time in a wet heat environment, the coating layer surface side of the support and the coating layer may be bonded to the polarizer.

### [Manufacturing Method of Polarizing Plate]

A manufacturing method of the polarizing plate is not particularly limited, and a known method can be used.

For example, the polarizer and the optical laminate are each produced, and the polarizer and the optical laminate are bonded to each other through an intimate attachment layer in a predetermined direction to manufacture the polarizing plate. Examples of the above-described intimate attachment layer include the above-described adhesion layer. As the polarizing plate manufactured by the method, it is preferable that the polarizer, an adhesion layer 1, the specific optically anisotropic layer (A), the specific optically anisotropic layer (B), the adhesion layer 2, and the C-plate are arranged adjacent to one another in this order. The adhesion layer 1 is a layer which adheres the polarizer and the optically anisotropic layer (A), and specific examples and suitable aspects thereof are the same as the adhesion layer which may be included in the optically anisotropic layer described above.

Here, the adhesion layer 2 and the C-plate may be included or may not be included, but it is preferable to include the C-plate from the viewpoint of optical characteristics. The C-plate may be disposed adjacent to the specific optically anisotropic layer (B) by the above-described method, that is, the configuration in which the C-plate is directly adjacent to the specific optically anisotropic layer (B) without including the adhesion layer 2 is also possible.

In addition, the polarizing plate in which the polarizer and the optical laminate are directly laminated may be manufactured by directly applying and forming a coating type polarizer on the optical laminate. As the polarizing plate manufactured by the method, it is preferable that the polarizer, the specific optically anisotropic layer (A), the specific optically anisotropic layer (B), the adhesion layer 2, and the C-plate are arranged adjacent to one another in this order. Here, the adhesion layer 2 and the C-plate may not be included, but it is preferable to include the C-plate from the viewpoint of optical characteristics. The C-plate may be disposed adjacent to the specific optically anisotropic layer (B) by the above-described method, that is, the configuration in which the C-plate is directly adjacent to the specific optically anisotropic layer (B) without including the adhesion layer 2 is also possible.

### [Organic EL Display Device]

The organic EL display device according to the embodiment of the present invention includes the above-described optical laminate or the above-described polarizing plate. In general, the optical laminate or the polarizing plate is provided on an organic EL display panel of the organic EL display device. That is, the organic EL display device according to the embodiment of the present invention includes the organic EL display panel, and the above-described optical laminate or the above-described polarizing plate.

The organic EL display panel is a member in which a light emitting layer or a plurality of organic compound thin films including a light emitting layer is formed between a pair of electrodes of an anode and a cathode; and in addition to the light emitting layer, a hole injection layer, a hole transport layer, an electron injection layer, an electron transport layer, a protective layer, and the like may be provided, and each of these layers may have a different function. Various materials can be used to form the respective layers.

### EXAMPLES

Hereinafter, features of the present invention will be described in more detail with reference to Examples and Comparative Example. The materials, amounts used, proportions, treatment details, and treatment procedure shown in the following Examples can be appropriately changed without departing from the spirit and scope of the present invention. Accordingly, the scope of the present invention should not be construed as being limited by the specific examples given below.

### Example 1

### Production of Cellulose Acylate Film (Substrate)

The following composition was put into a mixing tank, stirred, and further heated at 90° C. for 10 minutes. Thereafter, the obtained composition was filtered through a filter paper having an average hole diameter of 34 μm and a sintered metal filter having an average hole diameter of 10 μm to prepare a dope. The concentration of solid contents of the dope was 23.5% by mass, the amount of the plasticizer added was a proportion to cellulose acylate, and the solvent of the dope was methylene chloride/methanol/butanol=81/18/1 (mass ratio).

### Cellulose Acylate Dope

| | |
|---|---|
| Cellulose acylate (acetyl substitution degree: 2.86, | 100 parts by mass |
| viscosity average degree of polymerization: 310) | |
| Sugar ester compound 1 (represented by Chemical | 6.0 parts by mass |
| Formula (S4)) | |
| Sugar ester compound 2 (represented by Chemical | 2.0 parts by mass |
| Formula (S5)) | |
| Silica particle dispersion (AEROSIL R972, | 0.1 parts by mass |
| manufactured by Nippon Aerosil Co., Ltd.) | |
| Solvent (methylene chloride/methanol/butanol) | |

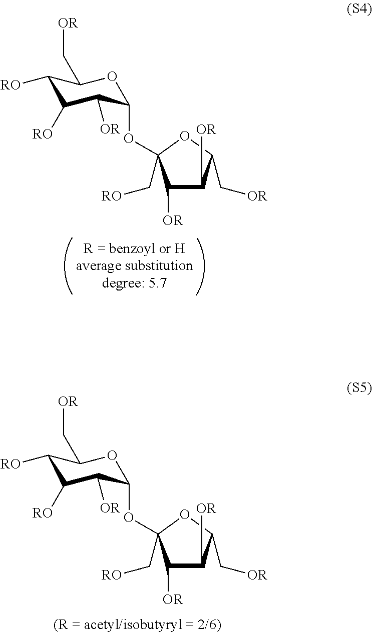

The dope produced above was cast using a drum film forming machine. The dope was cast from a die such that it was in contact with a metal support cooled to 0° C., and then the obtained web (film) was stripped from the drum. The drum was made of SUS.

The web (film) obtained by casting was peeled off from the drum, and then dried in a tenter device for 20 minutes at 30° C. to 40° C. during film transport, and the tenter device transported the web by clipping both ends of the web. Subsequently, the web was post-dried by zone heating while being rolled. The obtained web was knurled and then wound up.

In the obtained cellulose acylate film, a film thickness was 40 μm, an in-plane retardation Re(550) at a wavelength of 550 nm was 1 nm, and a thickness direction retardation Rth(550) at a wavelength of 550 nm was 26 nm.

### (Alkali Saponification Treatment)

After passing the above-described cellulose acylate film through a dielectric heating roll at a temperature of 60° C. to raise the film surface temperature to 40° C., an alkaline solution having the formulation shown below was applied onto a band surface of the film using a bar coater at a coating amount of 14 ml/m², followed by heating to 110° C., and transportation of the film under a steam type far-infrared heater manufactured by Noritake Company Limited for 10 seconds. Subsequently, pure water was applied at 3 ml/m² using the same bar coater. Next, after repeating washing with water by a fountain coater and draining by an air knife three times, the film was transported to a drying zone at 70° C. for 10 seconds and dried to produce a cellulose acylate film subjected to an alkali saponification treatment.

### Alkaline Solution

| | |
|---|---|
| Potassium hydroxide | 4.7 parts by mass |
| Water | 15.8 parts by mass |
| Isopropanol | 63.7 parts by mass |
| Surfactant: C₁₄H₂₉O(CH₂CH₂O)₂₀H | 1.0 parts by mass |
| Propylene glycol | 14.8 parts by mass |

### (Formation of Alignment Film)

An alignment film coating liquid having the following formulation was continuously applied onto the surface of the cellulose acylate film which had been subjected to the alkali saponification treatment with a #14 wire bar. The film was dried with hot air at 60° C. for 60 seconds, and further dried with hot air at 100° C. for 120 seconds.

### Alignment Film Coating Liquid

| | |
|---|---|
| Polyvinyl alcohol shown below | 10 parts by mass |
| Water | 371 parts by mass |
| Methanol | 119 parts by mass |
| Glutaraldehyde (crosslinking agent) | 0.5 parts by mass |
| Citric acid ester (manufactured by Sankyo | 0.175 parts by mass |
| Chemical Co., Ltd.) | |

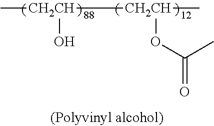

### (Formation of Optically Anisotropic Layer (A))

The alignment film produced above was continuously subjected to a rubbing treatment. In this case, the longitudinal direction and the transport direction of the elongated film were parallel to each other, and an angle between the longitudinal direction (transport direction) of the film and the rotation axis of the rubbing roller was 76°. In a case where the longitudinal direction (transport direction) of the film was defined as 90° and the clockwise direction was represented by a positive value with reference to a width direction of the film as a reference (0°) in a case of being observed from the film side, the rotation axis of the rubbing roller was −14°. In other words, the position of the rotation axis of the rubbing roller upon observation from the film side is a position rotated by 76° clockwise with reference to the longitudinal direction of the film.

A composition (1a) for forming an optically anisotropic layer, containing a disk-like liquid crystal compound with the following formulation, was applied onto the rubbing-treated alignment film using a Geeser coating machine to form a composition layer. Next, the obtained composition layer was heated with hot air at 110° C. for 2 minutes for drying of the solvent and alignment aging of the disk-like liquid crystal compound. Subsequently, the obtained composition layer was irradiated with UV (100 mJ/cm²) at 80° C. to fix the alignment of the liquid crystal compound to form an optically anisotropic layer (1a).

A thickness of the optically anisotropic layer (1a) was 1.1 μm. In addition, an in-plane retardation at a wavelength of 550 nm was 168 nm. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (1a) side, assuming that the in-plane slow axis angle of the optically anisotropic layer (1a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (1a) corresponds to the optically anisotropic layer (A) having a retardation not providing a λ/4 function.

### Composition (1a) for Forming Optically Anisotropic Layer

| | |
|---|---|
| Disk-like liquid crystal compound 1 shown below | 80 parts by mass |
| Disk-like liquid crystal compound 2 shown below | 20 parts by mass |
| Alignment film interface alignment agent 1 | 0.55 parts by mass |
| shown below | |
| Fluorine-containing compound A shown below | 0.1 parts by mass |
| Fluorine-containing compound B shown below | 0.05 parts by mass |
| Fluorine-containing compound C shown below | 0.21 parts by mass |
| Ethylene oxide-modified trimethylolpropane | 10 parts by mass |
| triacrylate (V#360, manufactured by Osaka | |
| Organic Chemical Ltd.) | |
| Photopolymerization initiator (IRGACURE 907, | 3.0 parts by mass |
| manufactured by BASF SE) | |
| Methyl ethyl ketone | 200 parts by mass |

### Disk-Like Liquid Crystal Compound 1

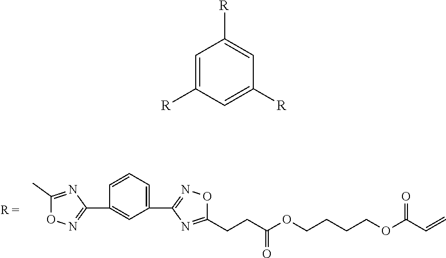

### Disk-Like Liquid Crystal Compound 2

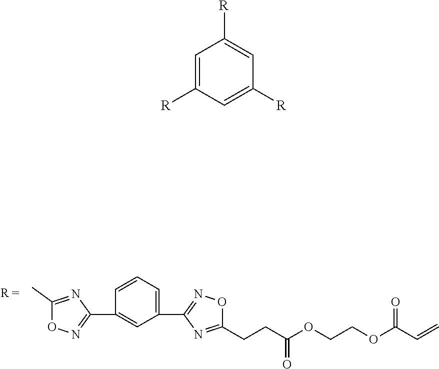

### Alignment Film Interface Alignment Agent 1

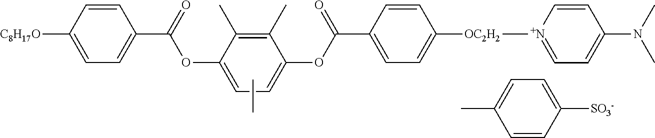

### Fluorine-Containing Compound A

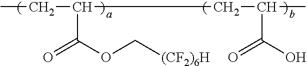

The a and b represent the content (% by mass) of each repeating unit with respect to all repeating units, and a represents 90% by mass and b represents 10% by mass.

Fluorine-containing compound B (the numerical value in each repeating unit represents the content (% by mass) with respect to all the repeating units; and the content of the repeating unit on the left side was 32.5% by mass and the content of the repeating unit on the right side was 67.5% by mass)

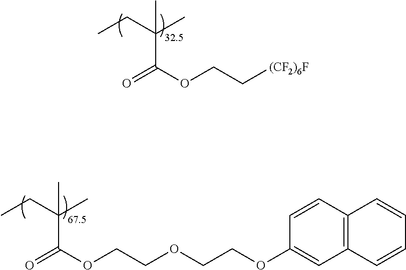

Fluorine-containing compound C (the numerical value in each repeating unit represents the content (% by mass) with respect to all the repeating units; and the content of the repeating unit on the left side was 25% by mass, the content of the repeating unit in the middle was 25% by mass, and the content of the repeating unit on the right side was 50% by mass)

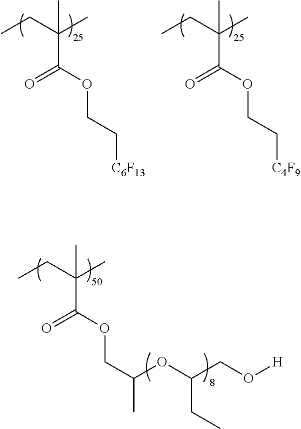

### (Formation of Laminate of Optically Anisotropic Layer (A) and Optically Anisotropic Layer (B))

### (Formation of Optically Anisotropic Layer (1b))

A surface of the above-described produced optically anisotropic layer (1a) as the optically anisotropic layer (A) was subjected to a corona treatment under conditions of 50 W·min/m², and a composition (1b) for forming an optically anisotropic layer, containing a rod-like liquid crystal compound with the following composition, was applied onto the surface subjected to the corona treatment using a gear coater, and heated with hot air at 80° C. for 60 seconds. Subsequently, the obtained composition layer was irradiated with UV (500 mJ/cm²) at 80° C. to fix the alignment of the liquid crystal compound to form an optically anisotropic layer (1b).

In the optically anisotropic layer (1b), a thickness was 1.2 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 85° on the air side and −14° on the side in contact with the optically anisotropic layer (1a), in a case of being viewed from the optically anisotropic layer (1b) side.

The alignment axial angle of the liquid crystal compound contained in the optically anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically anisotropic layer.

The optically anisotropic layer (1b) corresponds to the optically anisotropic layer (B) having a retardation not providing a λ/4 function.

### Composition (1b) for Forming Optically Anisotropic Layer

| | |
|---|---|
| Rod-like liquid crystal compound L-1 shown below | 100 parts by mass |
| Ethylene oxide-modified trimethylolpropane | 4 parts by mass |
| triacrylate (V#360, manufactured by Osaka | |
| Organic Chemical Ltd.) | |
| Photopolymerization initiator (Irgacure 819, | 3 parts by mass |
| manufactured by BASF SE) | |
| Left-handed twisting chiral agent (L1) shown below | 0.60 parts by mass |
| Fluorine-containing compound C shown above | 0.08 parts by mass |
| Methyl ethyl ketone | 156 parts by mass |

### Rod-Like Liquid Crystal Compound L-1

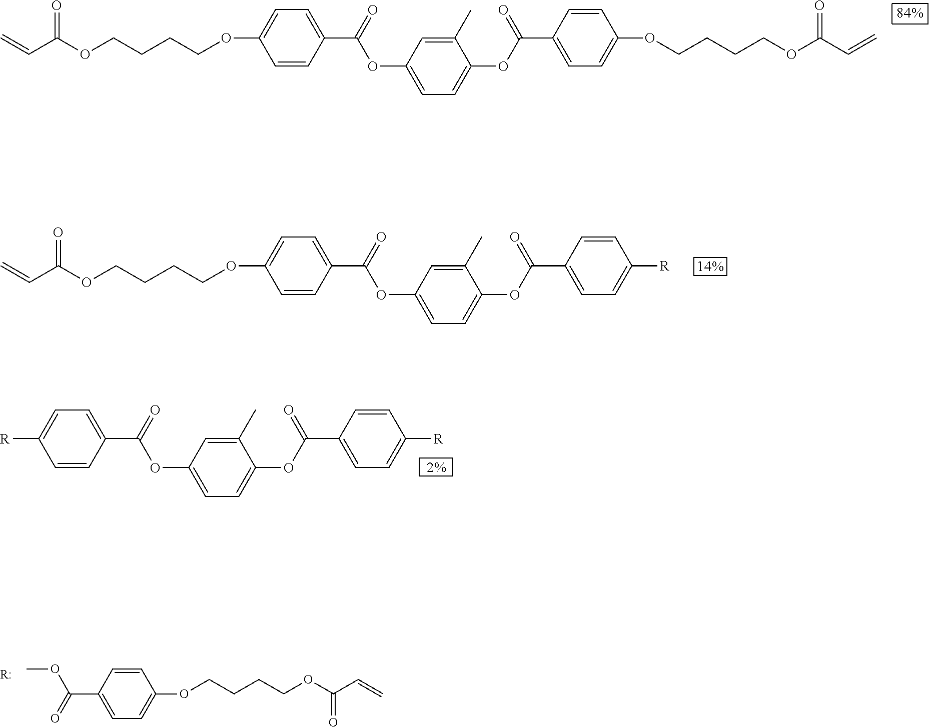

### Left-Handed Twisting Chiral Agent (L1)

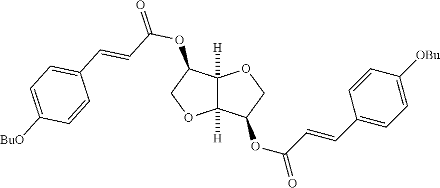

According to the above-described procedure, a laminate (1a-1b) in which the optically anisotropic layer (1a) and the optically anisotropic layer (1b) were directly laminated on the elongated cellulose acylate film was produced. The laminate (1a-1b) corresponds to the laminate having a λ/4 function.

### (Production of Optically Anisotropic Layer (C))

A composition 1c for forming an optically anisotropic layer shown below was applied onto the support produced in Example 1 using a gear coater to form a composition layer. A first temporary support on which the composition layer was formed was heated with hot air at 60° C. for 1 minute, and while performing nitrogen purging so that the oxygen concentration was 100 ppm or less, the composition layer was irradiated with ultraviolet rays (irradiation amount: 120 mJ/cm², using an ultra-high pressure mercury lamp) to fix the alignment of the rod-like liquid crystal compound L-1, thereby forming an optically anisotropic layer (1c).

A film thickness of the optically anisotropic layer (1c) was 0.7 μm. Re(550) of the optically anisotropic layer (1c) was 0 nm, and Rth(550) thereof was-80 nm. An average tilt angle with respect to the surface of the optically anisotropic layer of the rod-like liquid crystal compound L-1 was 90°, and the rod-like liquid crystal compound L-1 was vertically aligned with respect to the surface of the support.

### Composition (1c) for Forming Optically Anisotropic Layer

| | |
|---|---|
| Rod-like liquid crystal compound L-1 shown | 100 parts by mass |
| above | |
| Polyfunctional monomer (UA-306I, manufactured | 5.0 parts by mass |
| by KYOEISHA CHEMICAL Co., LTD.) | |
| Polymerization initiator (Irgacure OXE01, | 4.0 parts by mass |
| manufactured by BASF) | |
| Polymer X-1 shown below | 1.2 parts by mass |
| Onium salt compound shown below | 1.14 parts by mass |
| Fluorine-containing compound (fluorine- | 0.4 parts by mass |
| containing polymer) F-1 shown below | |
| Methyl ethyl ketone | 43.3 parts by mass |
| Ethyl propionate | 95.0 parts by mass |
| Methyl isobutyl ketone | 494.9 parts by mass |

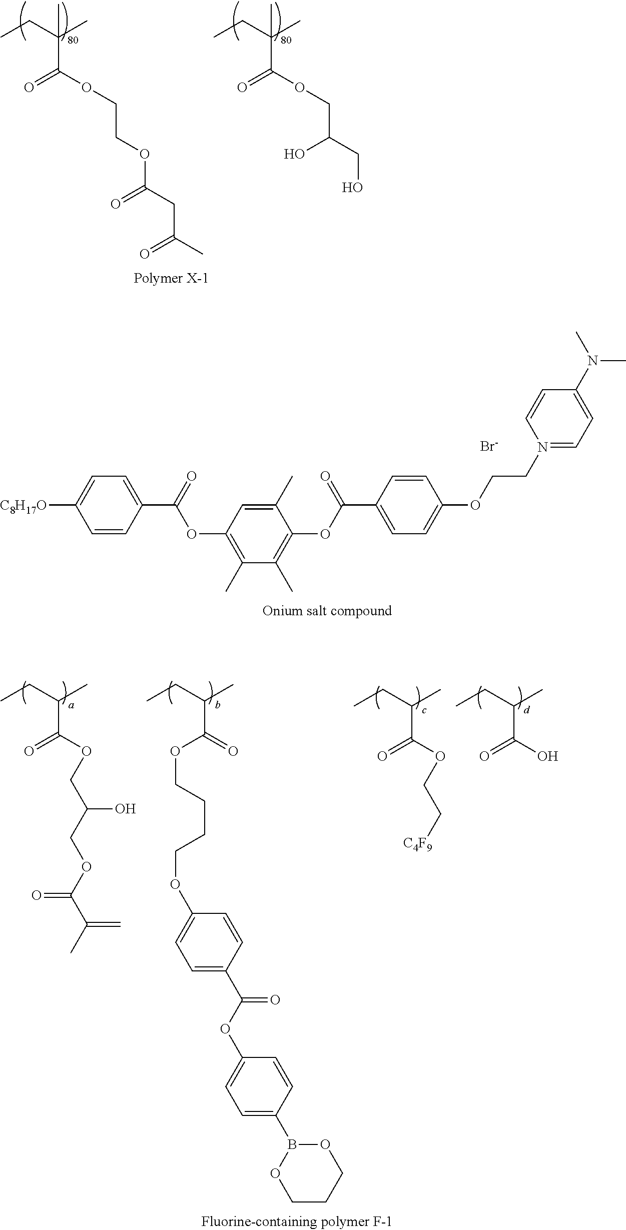

### (Formation of Laminate of Optically Anisotropic Layer (A), Optically Anisotropic Layer (B), and Optically Anisotropic Layer (C))

A surface side of the optically anisotropic layer (1a) formed on the elongated cellulose acylate film produced as described above, and a surface side of the optically anisotropic layer (1b) of the laminate (1a-1b) formed on the elongated cellulose acylate film produced as described above were bonded to each other using an ultraviolet curable adhesive in a continuous manner. A thickness of the ultraviolet curable adhesive was 1.0 μm, and a refractive index thereof was 1.54.

Subsequently, the cellulose acylate film with the rubbed alignment film on the optically anisotropic layer (1a) side was peeled off to expose the surface of the optically anisotropic layer (1a) on the cellulose acylate film side. In this manner, a retardation film (1c-1b-1a) in which the optically anisotropic layer (1c), the optically anisotropic layer (1b), and the optically anisotropic layer (1a) were laminated in this order on the elongated cellulose acylate film was obtained. A thickness of the retardation film (1c-1b-1a) was 4.0 μm.

### (Production of Linearly Polarizing Plate 1)

A surface of a support of a cellulose triacetate film TJ25 (manufactured by Fujifilm Corporation; thickness: 25 μm) was subjected to an alkali saponification treatment. Specifically, the support was immersed in a 1.5 N sodium hydroxide aqueous solution at 55° C. for 2 minutes, washed in a water bath at room temperature, and further neutralized with a 0.1 N sulfuric acid at 30° C. After neutralization, the support was washed in a water bath at room temperature and further dried with hot air at 100° C. to obtain a polarizer protective film.

A roll-like polyvinyl alcohol (PVA) film having a thickness of 60 μm was continuously stretched in an iodine aqueous solution in a longitudinal direction, and dried to obtain a polarizer having a thickness of 13 μm. The luminosity corrected single transmittance of the polarizer was 43%. In this case, an absorption axis direction of the polarizer coincided with the longitudinal direction.

The above-described polarizer protective film was bonded to one surface of the above-described polarizer using the following PVA adhesive to produce a linearly polarizing plate 1.

### (Preparation of PVA Adhesive)

100 parts by mass of a polyvinyl alcohol-based resin having an acetoacetyl group (average degree of polymerization: 1200, degree of saponification: 98.5 mol %, degree of acetoacetylation: 5 mol %) and 20 parts by mass of methylol melamine were dissolved in pure water under a temperature condition of 30° C. to prepare a PVA adhesive as an aqueous solution adjusted to a concentration of solid contents of 3.7% by mass.

### (Production of Circular Polarization Plate)

A surface of the elongated retardation film (1c-1b-1a) produced as described above on the optically anisotropic layer (1a) side and the surface of the polarizer (the surface opposite to the polarizer protective film) of the elongated linearly polarizing plate 1 produced as described above were continuously bonded to each other using an ultraviolet curable adhesive. Subsequently, the cellulose acylate film on the optically anisotropic layer (1c) side was peeled off to expose the surface of the optically anisotropic layer (1c) in contact with the cellulose acylate film.

In this way, a circular polarization plate (P1) consisting of the retardation film (1c-1b-1a) and the linearly polarizing plate was produced. In this case, the polarizer protective film, the polarizer, the optically anisotropic layer (1a), the optically anisotropic layer (1b), and the optically anisotropic layer (1c) were laminated in this order, and an angle formed by the absorption axis of the polarizer and the slow axis of the optically anisotropic layer (1a) was 76°. In addition, the alignment axial angle of the liquid crystal compound of the optically anisotropic layer (1b) on the optically anisotropic layer (1a) side was 14° with the width direction as a reference of 0°, which coincided with the slow axis direction of the optically anisotropic layer (1a). A thickness of the circular polarization plate was 43 μm.

The alignment axial angle of the liquid crystal compound contained in the optically anisotropic layer is expressed as negative in a case where it is clockwise (right-handed turning) and positive in a case where it is counterclockwise (left-handed turning) with the width direction of the linearly polarizing plate as a reference of 0°, upon observation from the surface side of the polarizing plate.

### Example 2

A circular polarization plate was produced by the same method as in Example 1, except for the method of forming the laminate of the optically anisotropic layer (A) and the optically anisotropic layer (B).

### (Formation of Optically Anisotropic Layer (A))

A composition (2a) for forming an optically anisotropic layer, containing a disk-like liquid crystal compound with the following formulation, was applied onto the rubbing-treated alignment film produced in Example 1 using a Geeser coating machine to form a composition layer. Next, the obtained composition layer was heated with hot air at 110° C. for 2 minutes for drying of the solvent and alignment aging of the disk-like liquid crystal compound. Subsequently, the obtained composition layer was irradiated with UV (100 mJ/cm²) at 80° C. to fix the alignment of the liquid crystal compound. Thereafter, the film was annealed with hot air at 120° C. for 1 minute to form an optically anisotropic layer (2a).

A thickness of the optically anisotropic layer (2a) was 1.1 μm. In addition, an in-plane retardation at a wavelength of 550 nm was 168 nm. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (2a) side, assuming that the in-plane slow axis angle of the optically anisotropic layer (2a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (2a) corresponds to the optically anisotropic layer (A) having a retardation not providing a λ/4 function.

### Composition (2a) for Forming Optically Anisotropic Layer

| | |
|---|---|
| Disk-like liquid crystal compound 1 of Example 1 | 80 parts by mass |
| Disk-like liquid crystal compound 2 of Example 1 | 20 parts by mass |
| Alignment film interface alignment agent 1 of | 0.55 parts by mass |
| Example 1 | |
| photo alignment polymer A-1 shown below | 2.0 parts by mass |
| Ethylene oxide-modified trimethylolpropane | 10 parts by mass |
| triacrylate (V#360, manufactured by Osaka | |
| Organic Chemical Ltd.) | |
| Photopolymerization initiator (IRGACURE 907, | 3.0 parts by mass |
| manufactured by BASF SE) | |
| Photoacid generator D-1 shown below | 3.0 parts by mass |
| Methyl ethyl ketone | 200 parts by mass |

photo alignment polymer A-1 (the numerical value described in each repeating unit represents the content (% by mass) of each repeating unit with respect to all the repeating units, which was 40% by mass, 25% by mass, and 35% by mass from the left repeating unit; in addition, a weight-average molecular weight was 69,300)

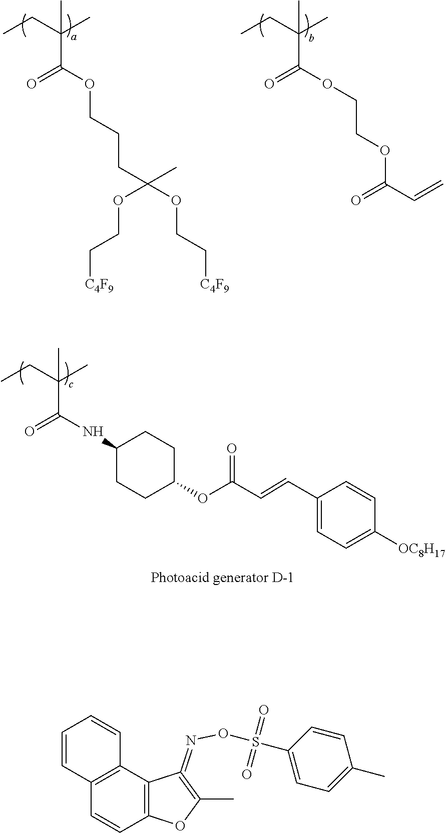

### (Formation of Laminate of Optically Anisotropic Layer (A) and Optically Anisotropic Layer (B))

### (Formation of Optically Anisotropic Layer (2b))

The obtained optically anisotropic layer (2a) was irradiated with UV light (ultra-high pressure mercury lamp; UL750; manufactured by HOYA Corporation) at 7.9 mJ/cm² (wavelength: 313 nm) through a wire grid polarizer at room temperature to align the alignment component (cinnamate moiety) of the photo alignment polymer A-1, thereby forming an optically anisotropic layer (2a) having an alignment function on the surface. Next, the composition (1b) for forming an optically anisotropic layer, containing the same rod-like liquid crystal compound as in Example 1, was applied onto the surface irradiated with UV light using a gear coater, and heated with hot air at 80° C. for 60 seconds. Subsequently, the obtained composition layer was irradiated with UV (500 mJ/cm²) at 80° C. to fix the alignment of the liquid crystal compound, thereby forming an optically anisotropic layer (2b).

In the optically anisotropic layer (2b), a thickness was 1.2 μm, And at a wavelength of 550 nm was 164 nm, and a twisted angle of the liquid crystal compound was 81°. Assuming that a width direction of the film is defined as 0° (a longitudinal direction of the film is defined as) 90°, the alignment axial angle of the liquid crystal compound was 85° on the air side and −14° on the side in contact with the optically anisotropic layer (2a), in a case of being viewed from the optically anisotropic layer (2b) side.

The optically anisotropic layer (2b) corresponds to the optically anisotropic layer (B) having a retardation not providing a λ/4 function.

According to the above-described procedure, a laminate (2a-2b) in which the optically anisotropic layer (2a) and the optically anisotropic layer (2b) were directly laminated on the elongated cellulose acylate film was produced. The laminate (2a-2b) corresponds to the laminate having a λ/4 function.

### Example 3

A circular polarization plate was produced by the same method as in Example 1, except that the thickness of the ultraviolet curable adhesive was changed to 1.0 μm and the refractive index thereof was changed to 1.51.

### Example 4

A circular polarization plate was produced by the same method as in Example 1, except for the methods of forming the optically anisotropic layer (A), the optically anisotropic layer (B), and the optically anisotropic layer (C).

### (Formation of Optically Anisotropic Layer (A))

A composition (3a) for forming an optically anisotropic layer, containing a disk-like liquid crystal compound with the following formulation, was applied onto the rubbing-treated alignment film produced in Example 1 using a Geeser coating machine to form a composition layer. Next, the obtained composition layer was heated with hot air at 110° C. for 2 minutes for drying of the solvent and alignment aging of the disk-like liquid crystal compound. Subsequently, the obtained composition layer was irradiated with UV (100 mJ/cm²) at 80° C. to fix the alignment of the liquid crystal compound. Thereafter, the film was annealed with hot air at 120° C. for 1 minute to form an optically anisotropic layer (3a).

A thickness of the optically anisotropic layer (3a) was 1.4 μm. In addition, an in-plane retardation at a wavelength of 550 nm was 168 nm. It was confirmed that an average tilt angle of a disc plane of the disk-like liquid crystal compound with respect to the film surface was 90°, and the disk-like liquid crystal compound was aligned perpendicular to the film surface. In addition, in a case of viewing from the optically anisotropic layer (3a) side, assuming that the in-plane slow axis angle of the optically anisotropic layer (3a) was parallel to the rotation axis of the rubbing roller, and the width direction of the film was 0° (the counterclockwise direction was 90° and the clockwise direction was −90° in the longitudinal direction), the in-plane slow axis was −14°.

The optically anisotropic layer (3a) corresponds to the optically anisotropic layer (A) having a retardation not providing a λ/4 function.

### Composition (3a) for Forming Optically Anisotropic Layer

| | |
|---|---|
| Disk-like liquid crystal compound 1 of Example 1 | 80 parts by mass |
| Disk-like liquid crystal compound 2 of Example 1 | 20 parts by mass |
| Alignment film interface alignment agent 1 of | 1.0 part by mass |
| Example 1 | |
| Silicon-containing compound A shown below | 0.2 parts by mass |
| Ethylene oxide-modified trimethylolpropane | 5 parts by mass |
| triacrylate (V#360, manufactured by Osaka | |
| Organic Chemical Industry Ltd.) | |
| Photopolymerization initiator (IRGACURE 907, | 4.0 parts by mass |
| manufactured by BASF SE) | |
| Methyl ethyl ketone | 200 parts by mass |

Silicon-containing compound A (in the following formula, a, b, c, and d represent the content (mol %) of each repeating unit with respect to all the repeating units, and a was 78 mol %, b was 10 mol %, c was 1 mol %, and d was 11 mol %; a weight-average molecular weight thereof was 13,500)

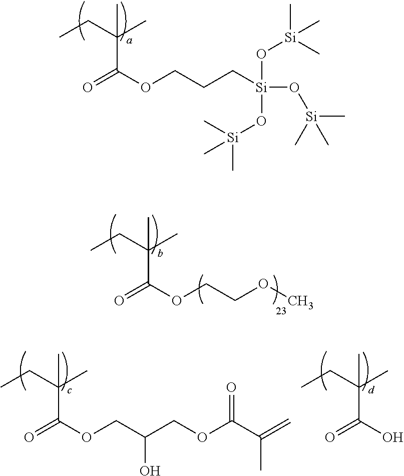

### (Formation of Laminate of Optically Anisotropic Layer (A) and Optically Anisotropic Layer (B))

### (Formation of Optically Anisotropic Layer (3b))

A surface of the above-described produced optically anisotropic layer (3a) as the optically anisotropic layer (A) was subjected to a corona treatment under conditions of 50 W·min/m², and a composition (3b) for forming an optically anisotropic layer, containing a rod-like liquid crystal compound with the following composition, was applied onto the surface subjected to the corona treatment using a gear coater, and heated with hot air at 80° C. for 60 seconds. Subsequently, the obtained composition layer was irradiated with UV (500 mJ/cm²) at 80° C. to fix the alignment of the liquid crystal compound, thereby forming an optically anisotropic layer (3b).

### Composition (3b) for Forming Optically Anisotropic Layer

| | |
|---|---|
| Rod-like liquid crystal compound L-1 of | 100 parts by mass |
| Example 1 | |
| Ethylene oxide-modified trimethylolpropane | 4 parts by mass |
| triacrylate (V#360, manufactured by | |
| Osaka Organic Chemical Ltd.) | |
| Photopolymerization initiator (Irgacure 819, | 3 parts by mass |
| manufactured by BASF SE) | |
| Left-handed twisting chiral agent (L1) of | 0.60 parts by mass |
| Example 1 | |
| Silicon-containing compound B shown below | 0.15 parts by mass |
| Methyl ethyl ketone | 156 parts by mass |

Silicon-containing compound B (in the following formula, a, b, and c represent the content (% by mass) of each repeating unit with respect to all repeating units, and a was 56% by mass, b was 36% by mass, and c was 8% by mass; a weight-average molecular weight thereof was 17,000)

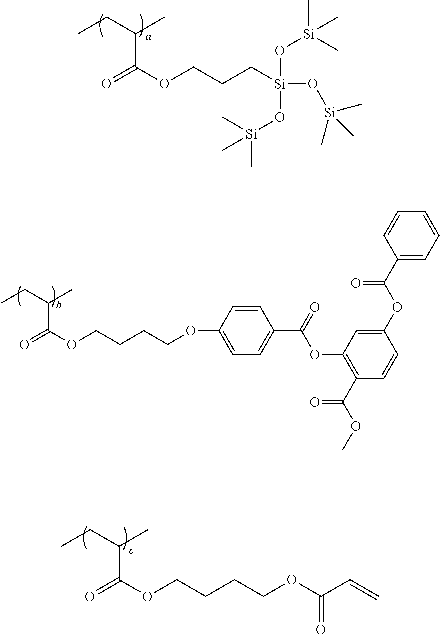

### (Production of Optically Anisotropic Layer (C))

The following liquid crystal composition (3c) was applied onto the support produced in Example 1 using a gear coater to form a composition layer. A first temporary support on which the composition layer was formed was heated with hot air at 60° C. for 1 minute, and while performing nitrogen purging so that the oxygen concentration was 100 ppm or less, the composition layer was irradiated with ultraviolet rays (irradiation amount: 120 mJ/cm², using an ultra-high pressure mercury lamp) to fix the alignment of the rod-like liquid crystal compound L-1, thereby forming an optically anisotropic layer (3c).

A film thickness of the optically anisotropic layer (3c) was 0.7 μm. Re(550) of the optically anisotropic layer (1c) was 0 nm, and Rth(550) thereof was-80 nm. An average tilt angle with respect to the surface of the optically anisotropic layer of the rod-like liquid crystal compound L-1 was 90°, and the rod-like liquid crystal compound L-1 was vertically aligned with respect to the surface of the support.

### Composition (3c) for Forming Optically Anisotropic Layer

| | |
|---|---|
| Rod-like liquid crystal compound L-1 shown | 100 parts by mass |
| above | |
| Polyfunctional monomer (UA-306I, manufactured | 5.0 parts by mass |
| by KYOEISHA CHEMICAL Co., LTD.) | |
| Polymerization initiator (Irgacure OXE01, | 4.0 parts by mass |
| manufactured by BASF) | |
| Polymer X-1 of Example 1 | 1.2 parts by mass |
| Onium salt compound of Example 1 | 1.14 parts by mass |
| Silicon-containing compound C shown below | 0.04 parts by mass |
| Silicon-containing compound D shown below | 0.21 parts by mass |
| Methyl ethyl ketone | 43.3 parts by mass |
| Ethyl propionate | 95.0 parts by mass |
| Methyl isobutyl ketone | 494.9 parts by mass |

Silicon-containing compound C (weight-average molecular weight: 20,000, in the following formula, the number represents the content (mass %) of each repeating unit with respect to all the repeating units in the silicon-containing compound C)

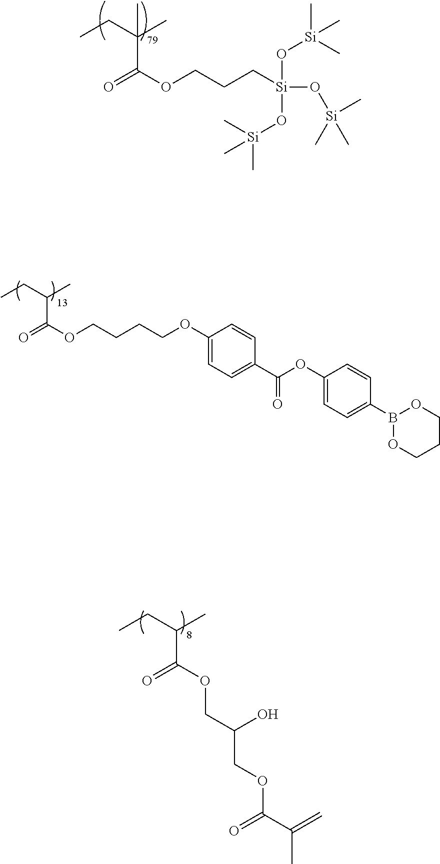

Silicon-containing compound D (weight-average molecular weight: 30,000, in the following formula, the number represents the content (mass %) of each repeating unit with respect to all the repeating units in the silicon-containing compound D)

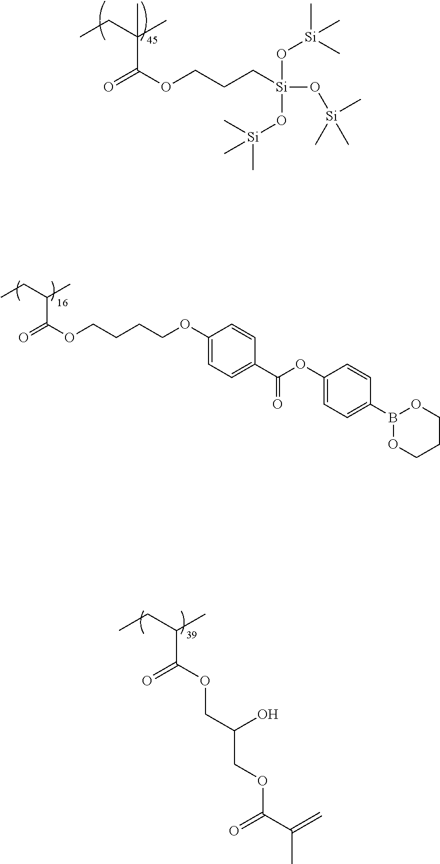

### Comparative Example 1

A laminate (1c-1b-1a) was produced by the same method as in Example 3, except that the composition (1b) for forming an optically anisotropic layer was applied onto the rubbed alignment film produced in Example 1 instead of the optically anisotropic layer (1a) to form the optically anisotropic layer (B), and the optically anisotropic layer (1a) and the optically anisotropic layer (1b) were bonded to each other using an ultraviolet curable adhesive having a refractive index of 1.51 in a continuous manner to produce a laminate (1a-1b); and then a circular polarization plate was produced.

### [Evaluation of Unevenness in Interference Color]

The produced circular polarization plate was bonded to a blackboard using a pressure sensitive adhesive such that the polarizer protective film was disposed on the outer side. Tint was observed from all directions through a diffusion plate under fluorescence (FPL-27EX-N). Azimuthal angle dependence of change in tint was evaluated according to the following standard.
A: in-plane tint unevenness was not visible at all, or the in-plane tint unevenness was visible, but only a little (acceptable).
B: in-plane tint unevenness was visible, but the reflected light was small and there was no problem in use (acceptable).
C: in-plane tint unevenness was visible, which was not acceptable.

TABLE 1

| | Layer | | | | Uneven- |
|---|---|---|---|---|---|
| | configur- | Type of | | Refractive | ness in |
| | ation | liquid | | index of | inter- |
| | of optical | crystal | Alignment | adhesive | ference |
| | laminate | compound | state | layer | color |
| Example 1 | A (1a) | Disk-like | Vertical | — | A |
| | B (1b) | Rod-like | Twisted | — | |
| | Adhesive | — | — | 1.54 | |
| | layer | | | | |
| | C (1c) | Rod-like | Vertical | — | |
| Example 2 | A (2a) | Disk-like | Horizontal | — | A |
| | B (2b) | Rod-like | Vertical | — | |
| | Adhesive | — | — | 1.54 | |
| | layer | | | | |
| | C (1c) | Rod-like | Twisted | — | |
| Example 3 | A (1a) | Disk-like | Vertical | — | B |
| | B (1b) | Rod-like | Twisted | — | |
| | Adhesive | — | — | 1.51 | |
| | layer | | | | |
| | C (1c) | Rod-like | Vertical | — | |
| Example 4 | A (3a) | Disk-like | Vertical | — | A |
| | B (3b) | Rod-like | Twisted | — | |
| | Adhesive | — | — | 1.54 | |
| | layer | | | | |
| | C (3c) | Rod-like | Vertical | — | |
| Comparative | A (1a) | Disk-like | Vertical | — | C |
| Example 1 | Adhesive | — | — | 1.51 | |
| | layer | | | | |
| | B (1b) | Rod-like | Twisted | — | |
| | Adhesive | — | — | 1.51 | |
| | layer | | | | |
| | C (1c) | Rod-like | Vertical | — | |

The circular polarization plates produced in each of Examples and Comparative Example were bonded to an aluminum plate using a pressure sensitive adhesive such that the polarizer protective film was disposed on the outer side, and reflection color was confirmed from the front direction and the oblique direction under a white light source. As a result, in any of Examples, no tint was observed or only a slight tint was observed, and the display performance in the front direction and the oblique direction was favorable.

From the above results, it was found that, in a case where the circular polarization plate including the optical laminate according to the embodiment of the present invention was used in the organic EL display device, the display performance in the front direction and the oblique direction was also favorable while suppressing the unevenness in interference color. On the other hand, the circular polarization plate of Comparative Example did not obtain a desired effect in a case where the circular polarization plate was used in the organic EL display device.

From the comparison between Example 3 and other examples, it was found that, in a case where the refractive index of the adhesion layer 2 was 1.53 to 1.64, the unevenness in interference color could be further suppressed.

### EXPLANATION OF REFERENCES

12: optically anisotropic layer (A)
14: optically anisotropic layer (B)
16: optically anisotropic layer (C)
20: polarizer
100: circular polarization plate
121, 122, 141, 142: surface

What is claimed is:

1. A manufacturing method of an optical laminate, comprising:
a step of directly applying a liquid crystal composition for forming an optically anisotropic layer (B) having a phase difference not providing a λ/4 function onto an optically anisotropic layer (A) formed by immobilizing an aligned liquid crystal compound, the optically anisotropic layer (A) satisfying the following requirement 1 or 2 and having a phase difference not providing a λ/4 function, to form a laminate having a λ/4 function,
the requirement 1: the optically anisotropic layer (A) is subjected to a surface treatment,
the requirement 2: the optically anisotropic layer (A) is formed of a liquid crystal composition containing a photo alignment polymer.

2. The manufacturing method of an optical laminate according to claim 1,
wherein the optically anisotropic layer (A) is a negative uniaxial optically anisotropic layer.

3. The manufacturing method of an optical laminate according to claim 1,
wherein the optically anisotropic layer (B) is an optically anisotropic layer formed by immobilizing a twisted-aligned rod-like liquid crystal compound having a helical axis along a thickness direction.

4. The manufacturing method of an optical laminate according to claim 1, further comprising:
a step of directly applying a liquid crystal composition for forming a C-plate onto the laminate to form a C-plate, or a step of bonding a C-plate to the laminate through an adhesion layer.

5. A manufacturing method of a polarizing plate, comprising:
laminating the optical laminate obtained by the manufacturing method of an optical laminate according to claim 1 and a polarizer to obtain a polarizing plate.

6. An optical laminate having a λ/4 function, comprising:
an optically anisotropic layer (A) which is formed by immobilizing an aligned liquid crystal compound, satisfies the following requirement 1 or 2, and has a phase difference not providing a λ/4 function;
an optically anisotropic layer (B) having a phase difference not providing a λ/4 function;
an adhesion layer 2; and
a C-plate,
wherein the optically anisotropic layer (A), the optically anisotropic layer (B), the adhesion layer 2, and the C-plate are arranged adjacent to one another in this order,
the requirement 1: the optically anisotropic layer (A) is subjected to a surface treatment,
the requirement 2: the optically anisotropic layer (A) is formed of a liquid crystal composition containing a photo alignment polymer.

7. The optical laminate according to claim 6,
wherein the adhesion layer 2 has a refractive index of 1.53 to 1.64.

8. The optical laminate according to claim 6,
wherein silicon is present at an interface between the optically anisotropic layer (A) and the optically anisotropic layer (B).

9. A polarizing plate comprising:
a polarizer;
an adhesion layer 1;
an optically anisotropic layer (A) which is formed by immobilizing an aligned liquid crystal compound, satisfies the following requirement 1 or 2, and has a phase difference not providing a λ/4 function;
an optically anisotropic layer (B) having a phase difference not providing a λ/4 function;
an adhesion layer 2; and
a C-plate,
wherein the polarizer, the adhesion layer 1, the optically anisotropic layer (A), the optically anisotropic layer (B), the adhesion layer 2, and the C-plate are arranged adjacent to one another in this order, and
a laminate of the optically anisotropic layer (A) and the optically anisotropic layer (B) has a λ/4 function,
the requirement 1: the optically anisotropic layer (A) is subjected to a surface treatment,
the requirement 2: the optically anisotropic layer (A) is formed of a liquid crystal composition containing a photo alignment polymer.

10. An organic electroluminescent display device comprising:
the optical laminate according to claim 6.

11. An organic electroluminescent display device comprising:
the polarizing plate according to claim 9.
